(19) United States
(12) Patent Application Publication
(10) Pub. No.: US 2019/0006570 A1
(43) Pub. Date: Jan. 3, 2019

(54) THERMOELECTRIC CONVERSION ELEMENT, METHOD FOR MANUFACTURING THERMOELECTRIC CONVERSION ELEMENT, THERMOELECTRIC CONVERSION MODULE, AND METHOD FOR MANUFACTURING THERMOELECTRIC CONVERSION MODULE

(71) Applicant: FUJIFILM Corporation, Tokyo (JP)

(72) Inventors: Hiroki SUGIURA, Ashigara-kami-gun (JP); Yoshinori KANAZAWA, Ashigara-kami-gun (JP); Naoyuki HAYASHI, Ashigara-kami-gun (JP); Kimiatsu NOMURA, Ashigara-kami-gun (JP)

(73) Assignee: FUJIFILM Corporation, Tokyo (JP)

(21) Appl. No.: 16/124,289

(22) Filed: Sep. 7, 2018

Related U.S. Application Data
(63) Continuation of application No. PCT/JP2017/008731, filed on Mar. 6, 2017.

(30) Foreign Application Priority Data
Mar. 9, 2016 (JP) 2016-045481

(51) Int. Cl. H01L 35/08; H01L 35/24; H01L 35/32; H01L 35/34; H01L 51/00

(52) U.S. Cl. CPC H01L 35/08; H01L 35/24; H01L 35/32; H01L 35/34; H01L 51/0093; H01L 51/005; H01L 51/004; H01L 51/0036; H01L 51/0048

(57) ABSTRACT

An object of the present invention is to provide a thermoelectric conversion element having excellent thermoelectric conversion performance and excellent high-temperature durability, a method for manufacturing the thermoelectric conversion element, a thermoelectric conversion module, and a method for manufacturing the thermoelectric conversion module. A thermoelectric conversion element of the present invention has a thermoelectric conversion layer containing an organic thermoelectric conversion material and a dopant, a pair of electrodes disposed at positions separated from each other, and a buffer layer which is disposed between the thermoelectric conversion layer and each of the electrodes and electrically connects the thermoelectric conversion layer and the electrodes to each other, in which the buffer layer contains the same material as the organic thermoelectric conversion material contained in the thermoelectric conversion layer, the buffer layer does not contain a dopant or contains a dopant, and in a case where the buffer layer contains a dopant, a ratio of the dopant contained in the buffer layer to the dopant contained in the thermoelectric conversion layer is equal to or lower than 0.1.

### CROSS-REFERENCE TO RELATED APPLICATIONS

This application is a Continuation of PCT International Application No. PCT/JP2017/008731 filed on Mar. 6, 2017, which claims priority under 35 U.S.C. § 119(a) to Japanese Patent Application No. 2016-045481 filed on Mar. 9, 2016. The above application is hereby expressly incorporated by reference, in its entirety, into the present application.

### BACKGROUND OF THE INVENTION

### 1. Field of the Invention

The present invention relates to a thermoelectric conversion element, a method for manufacturing a thermoelectric conversion element, a thermoelectric conversion module, and a method for manufacturing a thermoelectric conversion module.

### 2. Description of the Related Art

Thermoelectric conversion materials that enable the interconversion of thermal energy and electric energy are used in thermoelectric generation elements or thermoelectric conversion elements such as a Peltier element. Thermoelectric generation using the thermoelectric conversion elements can convert thermal energy directly into electric power, does not require a moving portion, and hence is exploited in wrist watches operating by body temperature, power supplies for backwoods, and aerospace power supplies.

It is known that inorganic materials and organic materials (for example, an organic compound and a carbon material formed of carbon atoms such as graphite and carbon nanotubes) are used as main components of the thermoelectric conversion materials.

For example, JP2009-260173A discloses a thermoelectric conversion layer formed using an inorganic material (magnesium silicide) as a thermoelectric conversion material (claim 1 and the like).

However, in a case where an inorganic material is used as a thermoelectric conversion material, there is a problem in that a step of processing the inorganic material becomes complicated. Therefore, JP2014-33170A discloses an aspect in which an organic material such as a carbon nanotube is used as a thermoelectric conversion material (claim 1, claim 16, and the like).

### SUMMARY OF THE INVENTION

As described in JP2014-33170A, a thermoelectric conversion layer contains a dopant (for example, an acid component such as an oxidant) in some cases. In a case where the thermoelectric conversion layer is kept in a high-temperature environment, the dopant contained in the thermoelectric conversion layer corrodes an electrode (deterioration of high-temperature durability), and the performance of a thermoelectric conversion element having the thermoelectric conversion layer deteriorates in some cases.

In order to improve the performance of a thermoelectric conversion element, a buffer layer is provided between a thermoelectric conversion layer and an electrode in some cases. For example, JP2009-260173A discloses a case where an inorganic material is used as a material constituting the buffer layer.

In order to inhibit the aforementioned corrosion of an electrode, the inventors of the present invention prepared a thermoelectric conversion element having a buffer layer, which is formed of an inorganic material described in JP2009-260173A, between a thermoelectric conversion layer containing carbon nanotubes and a dopant as described in JP2014-33170A and an electrode. The inventors found that the interfacial resistance between the thermoelectric conversion layer and the buffer layer increased, and hence the thermoelectric conversion performance of the thermoelectric conversion element deteriorated.

Therefore, an object of the present invention is to provide a thermoelectric conversion element having excellent thermoelectric conversion performance and excellent high-temperature durability, a method for manufacturing the thermoelectric conversion element, a thermoelectric conversion module, and a method for manufacturing the thermoelectric conversion module.

Regarding the aforementioned object, the inventors of the present invention conducted an intensive examination. As a result, the inventors obtained knowledge that by using a buffer layer, which contains an organic thermoelectric conversion material of the same type as a thermoelectric conversion layer and does not contain a dopant, and setting a ratio of a dopant contained in the buffer layer to a dopant contained in the thermoelectric conversion layer to be equal to or lower than a predetermined value, a thermoelectric conversion element having excellent thermoelectric conversion performance and excellent high-temperature durability is obtained. Based on the knowledge, the inventors have accomplished the present invention.

That is, the inventors of the present invention found that the aforementioned object can be achieved by the following constitution.

[1] A thermoelectric conversion element comprising a thermoelectric conversion layer containing an organic thermoelectric conversion material and a dopant, a pair of electrodes disposed at positions separated from each other, and a buffer layer which is disposed between the thermoelectric conversion layer and each of the electrodes and electrically connects the thermoelectric conversion layer and the electrodes to each other, in which the buffer layer contains the same material as the organic thermoelectric conversion material contained in the thermoelectric conversion layer, the buffer layer does not contain a dopant or contains a dopant, and in a case where the buffer layer contains a dopant, a ratio of the dopant contained in the buffer layer to the dopant contained in the thermoelectric conversion layer is equal to or lower than 0.1.

[2] The thermoelectric conversion element described in [1], in which at least one of the thermoelectric conversion layer or the buffer layer contains a polymer compound.

[3] The thermoelectric conversion element described in [1] or [2], in which the dopant contains at least one kind of acid component selected from the group consisting of a Brønsted acid, a Lewis acid, an oxidant, and an acid generator.

[4] The thermoelectric conversion element described in [3], in which in a case where the dopant contains the Brønsted acid, pKa of the Brønsted acid is 1.5 to 8.

[5] The thermoelectric conversion element described in [3], in which in a case where the dopant contains the oxidant, an oxidation-reduction potential of the oxidant with respect to a saturated calomel reference electrode is equal to or higher than −0.1 V.

[6] The thermoelectric conversion element described in any one of [1] to [5], in which the buffer layer substantially does not contain a dopant.

[7] The thermoelectric conversion element described in any one of [1] to [6], in which the organic thermoelectric conversion material is a carbon material.

[8] The thermoelectric conversion element described in [7], in which the carbon material is a carbon nanotube.

[9] The thermoelectric conversion element described in [8], in which the carbon nanotube is a single-layer carbon nanotube.

[10] A method for manufacturing the thermoelectric conversion element described in any one of [1] to [9], in which a step of forming the thermoelectric conversion layer and a step of forming the buffer layer are simultaneously performed.

[11] A thermoelectric conversion module comprising a plurality of the thermoelectric conversion elements described in any one of [1] to [9].

[12] A method for manufacturing the thermoelectric conversion module described in [11], in which a step of forming the thermoelectric conversion layer and a step of forming the buffer layer are simultaneously performed.

As will be described below, according to the present invention, it is possible to provide a thermoelectric conversion element having excellent thermoelectric conversion performance and excellent high-temperature durability, a method for manufacturing the thermoelectric conversion element, a thermoelectric conversion module, and a method for manufacturing the thermoelectric conversion module.

### BRIEF DESCRIPTION OF THE DRAWINGS

FIG. 1 is a cross-sectional view of a first embodiment of a thermoelectric conversion element of the present invention.

FIG. 2 is a cross-sectional view of a second embodiment of the thermoelectric conversion element of the present invention.

FIG. 3 is a cross-sectional view of a third embodiment of the thermoelectric conversion element of the present invention.

FIG. 4A is a cross-sectional view of a fourth embodiment of the thermoelectric conversion element of the present invention.

FIG. 4B is a top view of the fourth embodiment of the thermoelectric conversion element of the present invention.

FIG. 5 is a schematic top view for illustrating the structure of a thermoelectric conversion module of the present invention.

FIG. 6 is a view for illustrating a method for evaluating thermoelectric conversion modules in examples.

### DESCRIPTION OF THE PREFERRED EMBODIMENTS

Hereinafter, the present invention will be specifically described.

In the present invention, a range of numerical values described using “to” means a range including the numerical values listed before and after “to” as a lower limit and an upper limit respectively.

In the present invention, a figure of merit Z is one of the indices for evaluating the thermoelectric conversion performance of a thermoelectric conversion element. The figure of merit Z is represented by Equation (A). For enhancing the thermoelectric conversion performance, it is important to improve a thermoelectromotive force S per absolute temperature of 1 K (hereinafter, referred to as a thermoelectromotive force in some cases) and an electric conductivity a and to reduce a thermal conductivity K.

Figure of merit Z=S²·σ/x (A)

In Equation (A), S (V/K) is a thermoelectromotive force (Seebeck coefficient) per absolute temperature of 1 K, σ (S/m) is an electric conductivity, and κ (W/mK) is a thermal conductivity.

One of the characteristics of the thermoelectric conversion element of the present invention is that the buffer layer does not contain a dopant, or a ratio of a dopant contained in the buffer layer to a dopant contained in the thermoelectric conversion layer is made equal to or lower than a predetermined value.

The inventors of the present invention found that in a case where the thermoelectric conversion element is kept in a high-temperature environment (for 7 days at 150° C.), the resistance of the thermoelectric conversion element increases. As the reason, the inventors consider that the dopant contained in the thermoelectric conversion layer may be diffused to the electrode and corrode the electrode.

The inventors of the present invention consider that by adopting a constitution in which the buffer layer does not contain a dopant or a ratio of a dopant contained in the buffer layer to a dopant contained in the thermoelectric conversion layer is made equal to or lower than a predetermined value, it is possible to prevent the diffusion of the dopant and to improve the high-temperature durability of the thermoelectric conversion element.

Another one of the characteristics of the thermoelectric conversion element of the present invention is that a buffer layer containing an organic thermoelectric conversion material of the same type as the thermoelectric conversion layer is used.

The inventors of the present invention found that in a case where a buffer layer is used, the corrosion of an electrode can be inhibited, but depending on the type of the thermoelectric conversion material contained in the buffer layer, the resistance of the thermoelectric conversion element increases, and the thermoelectric conversion performance deteriorates. The inventors consider that this is because the interfacial resistance between the thermoelectric conversion layer and the buffer layer increases.

Specifically, as shown in Examples, in a case where an inorganic material (tin oxide) is used as the thermoelectric conversion material contained in the buffer layer, the electric conductivity decreases (Comparative Example 5). Furthermore, even though both the thermoelectric conversion layer and the buffer layer contain an organic thermoelectric conversion material, in a case where the contained organic thermoelectric conversion materials are different from each other, the electric conductivity decreases (Comparative Example 4). The inventors consider that this is because the interfacial resistance increases due to the difference in the material between the thermoelectric conversion layer and the buffer layer.

The inventors of the present invention consider that by using a buffer layer containing an organic thermoelectric conversion material of the same type as the thermoelectric conversion layer, it is possible to reduce the interfacial resistance between the thermoelectric conversion layer and the buffer layer and to improve the thermoelectric conversion performance of the thermoelectric conversion element.

[Thermoelectric Conversion Element]

The thermoelectric conversion element of the present invention has a thermoelectric conversion layer containing an organic thermoelectric conversion material and a dopant, a pair of electrodes disposed at positions separated from each other, and a buffer layer which is disposed between the thermoelectric conversion layer and each of the electrodes and electrically connects the thermoelectric conversion layer and the electrodes to each other, in which the buffer layer contains the same material as the organic thermoelectric conversion material contained in the thermoelectric conversion layer, and the buffer layer does not contain a dopant or contains a dopant, and in a case where the buffer layer contains a dopant, a ratio of the dopant in the buffer layer to the dopant contained in the thermoelectric conversion layer is equal to or lower than 0.1.

Hereinbelow, the thermoelectric conversion element of the present invention will be described for each embodiment.

### First Embodiment

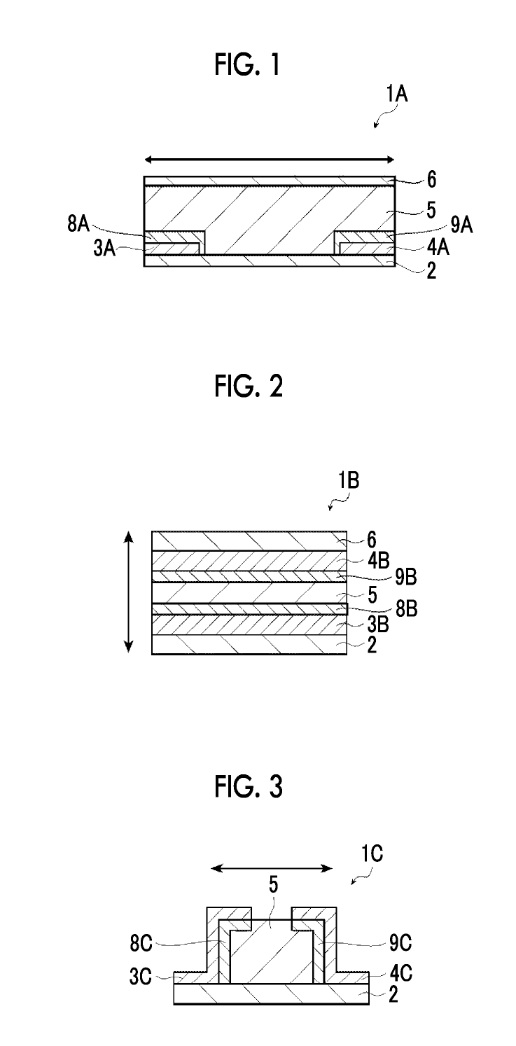

FIG. 1 is a view conceptually showing a thermoelectric conversion element of a first embodiment that is an example of the thermoelectric conversion element of the present invention.

As shown in FIG. 1, a thermoelectric conversion element 1A has a substrate 2, a first electrode 3A and a second electrode 4A disposed on the substrate 2 at positions spaced apart from each other, a first buffer layer 8A disposed to come into contact with the first electrode 3A on the substrate 2, a second buffer layer 9A disposed to come into contact with the second electrode 4A on the substrate 2, a thermoelectric conversion layer 5 disposed to come into contact with the first buffer layer 8A and the second buffer layer 9A on the substrate 2, and a protective substrate 6 disposed on the thermoelectric conversion layer 5. At the time of using the thermoelectric conversion element 1A, as shown in FIG. 1, a temperature difference is caused in the direction of the arrow.

As shown in FIG. 1, each of the buffer layers (the first buffer layer 8A and the second buffer layer 9A) is disposed between the thermoelectric conversion layer 5 and each of the electrodes (the first electrode 3A and the second electrode 4A), and electrically connects the thermoelectric conversion layer 5 and the electrodes to each other. That is, each of the buffer layers is disposed between the thermoelectric conversion layer and each of the electrodes such that the thermoelectric conversion layer and the electrodes do not come into direct contact with each other.

Hereinafter, each of the members constituting the thermoelectric conversion element will be specifically described.

<Substrate>

The type of the substrate is not particularly limited as long as the substrate can function to support various members which will be described later. However, it is preferable to select a substrate that is hardly affected by the formation of the electrodes or the formation of the thermoelectric conversion layer.

Examples of such a substrate include a resin substrate, a glass substrate, a transparent ceramic substrate, a metal substrate, and the like. Among these, from the viewpoint of cost and flexibility, a resin substrate is preferable.

More specifically, examples of the resin substrate include a polyester substrate such as polyethylene terephthalate, polyethylene isophthalate, polyethylene naphthalate, polubutylene terephthalate, poly(1,4-cyclohexylenedimethyleneterephthalate), and polyethylene-2,6-phthalenedicarboxylate, a polycycloolefin substrate such as a ZEONOR film (trade name, manufactured by ZEON CORPORATION), an ARTON film (trade name, manufactured by JSR Corporation), and SUMILITE FS1700 (trade name, manufactured by Sumitomo Bakelite Co. Ltd.), a polyimide substrate such as KAPTON (trade name, manufactured by DU PONT-TORAY CO., LTD.), APICAL (trade name, manufactured by Kaneka Corporation), UPILEX (trade name, manufactured by UBE INDUSTRIES, LTD.), and POMIRAN (trade name, manufactured by Arakawa Chemical Industries, Ltd.), a polycarbonate substrate such as PUREACE (trade name, manufactured by TEIJIN LIMITED) and ELMEC (trade name, manufactured by Kaneka Corporation), a polyether ether ketone substrate such as SUMILITE FS1100 (trade name, manufactured by Sumitomo Bakelite Co. Ltd.), a polyphenyl sulfide substrate such as TORELINA (trade name, manufactured by TORAY INDUSTRIES, INC.), a polyacetal substrate, a polyamide substrate, a polyphenylene ether substrate, a polyolefin substrate (for example, a polyethylene substrate), a polystyrene substrate, a polyacrylate substrate, a polysulfone substrate, a polyether sulfone substrate, a fluororesin substrate, a liquid crystal polymer substrate, and the like. Among these, a polyimide substrate is preferable because this substrate is easily obtained, has heat resistance (preferably resistance to a temperature equal to or higher than 100° C.), and further improves the effects of the present invention.

In view of handleability, durability, and the like, the thickness of the substrate is preferably 1 to 3,000 μm, more preferably 5 to 1,000 μm, even more preferably 5 to 100 and particularly preferably 5 to 50 μm.

As the resin substrate, for example, a resin substrate having undergone surface treatment by energy ray irradiation is preferable, because such a substrate further improves the thermoelectric conversion characteristics of the thermoelectric conversion element and/or the bending resistance of the thermoelectric conversion element. The resin substrate having undergone the aforementioned treatment exhibits better adhesiveness with respect to the thermoelectric conversion layer.

The method of the energy ray irradiation is not particularly limited, and for example, it is possible to use known treatment methods such as a corona treatment using corona discharge, a plasma treatment in which the substrate is exposed to a plasma atmosphere, an ultraviolet irradiation treatment in which ultraviolet irradiation is performed (preferably an ultraviolet (UV) ozone treatment in which ultraviolet irradiation is performed in an ozone atmosphere), and an electron beam (EB) irradiation treatment in which the substrate is irradiated with electron beams. Among these, a plasma treatment, a corona treatment, and a UV ozone treatment are preferable.

<First Electrode and Second Electrode>

The first electrode and the second electrode form a pair of electrodes disposed at separated positions. The electrodes are members which are disposed to come into contact with the buffer layer which will be described later and electrically connected to the thermoelectric conversion layer, which will be described later, through the buffer layer. Hereinafter, the first electrode and the second electrode will be collectively called “electrode” in some cases.

(Electrode Material)

The electrode material constituting the aforementioned electrode is not limited as long as it is a material having a desired electric conductivity.

Specifically, examples of the electrode material include a metal material such as copper, silver, gold, platinum, nickel, aluminum, constantan, chromium, indium, iron, and a copper alloy, a material such as indium tin oxide (ITO) and zinc oxide (ZnO) used as a transparent electrode in various devices, and the like. Among these electrode materials, copper, gold, silver, platinum, nickel, a copper alloy, aluminum, constantan, and the like are preferable, and copper, gold, silver, platinum, and nickel are more preferable.

(Method for Forming Electrode)

The electrode formation can be performed by a known method such as vapor deposition, printing (for example, screen printing, metal mask printing, ink jet printing, and the like), and bonding to a substrate through a pressure sensitive adhesive or an adhesive, according to the material forming the first electrode and the second electrode.

The electrode may be formed in the pattern shape by using a mask at the time of vapor deposition of printing. Alternatively, the electrode may be formed in a plane shape and then patterned by a known method such as etching, sand blasting, laser engraving, and an electron beam method.

<Thermoelectric Conversion Layer>

The thermoelectric conversion layer is a layer which is disposed to come into contact with the buffer layer, which will be described later, and electrically connected to the pair of electrodes described above through the buffer layer.

(Component Contained in Thermoelectric Conversion Layer)

The thermoelectric conversion layer contains an organic thermoelectric conversion material and a dopant. Hereinafter, the components contained in the thermoelectric conversion layer and components that can be contained in the thermoelectric conversion layer will be described.

((Organic Thermoelectric Conversion Material))

The thermoelectric conversion layer contains an organic thermoelectric conversion material. The organic thermoelectric conversion material refers to a thermoelectric conversion material containing an organic material. The organic material means a material containing carbon.

Examples of the organic thermoelectric conversion material include an organic compound such as a low-molecular weight organic semiconductor and a conductive polymer, a carbon material formed of carbon atoms, and the like. One kind of these materials may be used singly, or two or more kinds of these materials may be used in combination.

The low-molecular weight organic semiconductor refers to an organic semiconductor material which does not have a repeating unit in the chemical structure thereof. Examples of the low-molecular weight organic semiconductor include pentacenes such as 6,13-bis(triisopropylsilylethynyl)pentacene (TIPS pentacene), tetramethylpentacene, and perfluoropentacene, anthradithiophenes such as 5,11-bis(triethylsilylethynyl)anthradithiophene (TES-ADT) and 2,8-difluoro-5,11-bis(triethylsilylethynyl)anthradithiophene (diF-TES-ADT), benzothienobenzothiophenes such as diphenylbenzothienobenzothiophene (DPh-BTBT) and alkylbenzothienobenzothiophene (Cn-BTBT), dinaphthothienothiophenes such as alkyldinaphthothienothiophene (Cn-DNTT), dioxaanthanthrenes such as perixanthenoxanthene, rubrenes, fullerenes such as C60 and phenyl C₆₁ butyric acid methyl ester (PCBM), phthalocyanines such as copper phthalocyanine and fluorinated copper phthalocyanine, and the like.

The conductive polymer refers to a conductive material having a repeating unit in the chemical structure thereof. Examples of the conductive polymer include polythiophenes such as poly(3-alkylthiophene) (P3RT) and polyquarterthiophene (PQT), polythienothiophenes such as poly[2,5-bis(3-dodecylthiophen-2-yl)thieno[3,2-b]thiophene] (PBTTT), and the like.

Examples of the carbon material include a carbon nanotube (hereinafter, simply referred to as “CNT” as well), a carbon nanobud, a carbon nanohorn, a graphene nanoribbon, graphene, fullerene, and the like.

Among these, as the organic thermoelectric conversion material, a carbon material is preferable, and a carbon nanotube is more preferable. In a case where such a carbon material is used, the electric conductivity, the Seebeck coefficient, and/or the thermoelectric conversion performance of the thermoelectric conversion element are further improved, or the output of the thermoelectric conversion module is further improved.

CNT includes single-layer CNT formed of one sheet of carbon film (graphene sheet) wound in the form of a cylinder, double-layered CNT formed of two graphene sheets wound in the form of concentric circles, and multilayered CNT formed of a plurality of graphene sheets wound in the form of concentric circles. In the present invention, one kind of each of the single-layer CNT, the double-layered CNT, and the multilayered CNT may be used singly, or two or more kinds thereof may be used in combination. Particularly, the single-layer CNT having excellent properties in terms of electric conductivity and semiconductor characteristics and the double-layered CNT are preferably used, and the single-layer CNT is more preferably used.

The single-layer CNT may be semiconductive or metallic, and both the semiconductive CNT and the metallic CNT may be used in combination. In a case where both the semiconductive CNT and the metallic CNT are used, the content ratio between them can be appropriately adjusted according to the use. Furthermore, CNT may contain a metal or the like, and CNT containing molecules of fullerene and the like may also be used.

In the present invention, modified or treated CNT can also be used. Examples of the modification or treatment method include a method of incorporating a ferrocene derivative or nitrogen-substituted fullerene (azafullerene) into CNT, a method of doping CNT with an alkali metal (potassium or the like) or a metallic element (indium or the like) by an ion doping method, a method of heating CNT in a vacuum, and the like.

In a case where CNT is used, in addition to the single-layer CNT or the multilayered CNT, nanocarbons such as a carbon nanohorn, a carbon nanocoil, a carbon nanobead, graphite, graphene, and amorphous carbon, a metallic catalyst used at the time of synthesizing CNT, and the like may be contained in the thermoelectric conversion layer.

In view of further improving the performance of the thermoelectric conversion layer, the content of the organic thermoelectric conversion material in the thermoelectric conversion layer with respect to the total mass of the thermoelectric conversion layer is preferably 5% to 99% by mass, more preferably 50% to 90% by mass, and even more preferably 50% to 80% by mass.

The thermoelectric conversion layer may be in the form of a hybrid containing, in addition to the aforementioned organic thermoelectric conversion material, a known inorganic thermoelectric conversion material (thermoelectric conversion material containing an inorganic material).

((Dopant))

The thermoelectric conversion layer of the present invention contains a dopant. As the dopant, any of known dopants used in thermoelectric conversion layers can be used.

It is preferable that the dopant contains at least one kind of acid component selected from the group consisting of a Brønsted acid, a Lewis acid, an oxidant, and an acid generator. These acid components are used as a dopant which can make a thermoelectric conversion material into a p-type, that is, a so-called dopant for change into a p-type.

Examples of the Brønsted acid include an inorganic acid such as a hydrochloric acid, a sulfuric acid, a nitric acid, and a phosphoric acid and an organic acid such as a carboxylic acid (an aromatic carboxylic acid, an aliphatic carboxylic acid, and the like), a sulfonic acid, and a sulfinic acid.

In a case where the dopant contains a Brønsted acid, from the viewpoint of improving the thermoelectric conversion performance and preventing the electrode corrosion, a Brønsted acid having pKa of 1.5 to 8 is preferably used, and a Brønsted acid having pKa of 3 to 8 is more preferably used.

Examples of the Lewis acid include FeCl₃, AlCl₃, Fe(OTs)₃, PF₅, AsF₅, SbF₅, BF₃, BCl₃, BBr₃, SO₃, and the like. “Ts” represents a p-toluenesulfonyl group, and Fe(OTs)₃ represents iron (III) p-toluenesulfonate.

Examples of the oxidant include tetracyanoquinodimethane (TCNQ), tetrafluorotetracyanodimethane (F4-TCNQ), halogenated tetracyanoquinodimethane, 1,1-dicyanovinylene, 1,1,2-tricyanovinylene, benzoquinone, 2,3-dichloro-5,6-dicyano-p-benzoquinone (DDQ), pentafluorophenol, dicyanofluorenone, cyano-fluoroalkylsulfonyl-fluorenone, pyridine, pyrazine, triazine, tetrazine, pyridopirazine, benzothiadiazole, heterocyclic thiadiazole, porphyrin, phthalocyanine, a boron quinolate-based compound, a boron diketonate-based compound, a boron diisoindomethene-based compound, a carborane-based compound, other boron atom-containing compounds, and the like.

In a case where the dopant contains an oxidant, from the viewpoint of performing doping by oxidizing CNT, the oxidation-reduction potential of the used oxidant with respect to a saturated calomel reference electrode is preferably equal to or higher than −0.1 V and more preferably equal to or higher than 0 V. The upper limit of the oxidation-reduction potential is not limited, but is equal to or lower than 1.5 V in many cases.

The oxidation-reduction potential of each of the components in the present invention is measured by cyclic voltammetry by using a saturated calomel electrode as a reference electrode (saturated calomel reference electrode). Specifically, the oxidation-reduction potential is measured at room temperature (25° C.) by using a dichloromethane solution or an acetonitrile solution containing 0.1 M electrolyte (tetrabutylammonium hexafluorophosphate or tetrabutylammonium perchlorate) as an electrolytic solution at a sample concentration of 0.5 mM. Furthermore, as measurement conditions, a glassy carbon electrode is used as a working electrode, a platinum electrode is used as a counter electrode, and a sweep rate is set to be 5 mV/sec.

Examples of the acid generator include a compound (photoacid generator) generating an acid by being irradiated with active energy rays (radiation, electromagnetic waves, and the like) and a compound (thermal acid generator) generating an acid by the application of heat. As the acid generator, an onium salt compound is preferably used, and examples thereof include a sulfonium salt, an iodonium salt, an ammonium salt, a carbonium salt, a phosphonium salt, and the like. Among these, a sulfonium salt, an iodonium salt, an ammonium salt, and a carbonium salt are preferable, a sulfonium salt, an iodonium salt, and a carbonium salt are more preferable, and a sulfonium salt and an iodonium salt are even more preferable. Examples of an anion portion constituting these salts include a counter anion of a strong acid.

From the viewpoint of further improving the performance of the thermoelectric conversion layer, the content of the dopant in the thermoelectric conversion layer with respect to the total mass of the thermoelectric conversion layer is preferably 0.01% to 80% by mass, more preferably 0.1% to 75% by mass, and even more preferably 0.1% to 50% by mass.

((Polymer Compound))

In the present invention, it is preferable that at least one of the thermoelectric conversion material or the buffer layer, which will be described later, contains a polymer compound.

In a case where the thermoelectric conversion layer contains a polymer compound, the polymer compound can function as a binder and increase the distance between the organic thermoelectric conversion materials (particularly CNTs). As a result, the thermal conductivity can be reduced, and hence the figure of merit Z can be further improved.

Furthermore, the polymer compound also functions to inhibit the diffusion of the dopant.

Specifically, as the polymer compound, it is possible to use various known polymer compounds such as a vinyl compound, a (meth)acrylate compound, a carbonate compound, an ester compound, an epoxy compound, a siloxane compound, and gelatin. As the polymer compound, it is preferable to use a hydrogen bonding resin.

A hydrogen bonding functional group is not limited as long as it is a functional group having hydrogen bonding properties. Examples thereof include a OH group, an NH₂ group, an NHR group (R represents an aromatic or aliphatic hydrocarbon), a COOH group, a CONH₂ group, an NHOH group, a SO₃H group (sulfonic acid group), a —OP(═O)OH₂ group (phosphoric acid group), and a group having a —NHCO— group, a —NH— group, a —CONHCO— bond, a —NH—NH— bond, a —C(═O)— group (carbonyl group), an —ROR— group (ether group: R each independently represents a divalent aromatic hydrocarbon or a divalent aliphatic hydrocarbon. Here, two R's may be the same as or different from each other), and the like.

Examples of the hydrogen bonding resin (resin having a hydrogen bonding functional group) include carboxymethyl cellulose, carboxyethyl cellulose, methyl cellulose, ethyl cellulose, hydroxymethyl cellulose, hydroxyethyl cellulose, methyl hydroxypropyl cellulose, hydroxypropyl methylcellulose, crystalline cellulose, xanthan gum, guar gum, hydroxyethyl guar gum, carboxymethyl guar gum, gum tragacanth, locust bean gum, tamarind seed gum, psyllium seed gum, quince seeds, carrageenan, galactan, gum Arabic, pectin, pullulan, mannan, glucomannan, starch, curdlan, chondroitin sulfate, dermatan sulfate, glycogen, heparan sulfate, hyaluronic acid, keratan sulfate, chondroitin, mucoitin sulfate, dextran, keratosulfate, succinoglucan, karonin acid, alginic acid, propylene glycol alginate, macrogol, chitin, chitosan, carboxymethyl chitin, gelatin, agar, polyvinyl alcohol, polyvinyl pyrrolidone, a carboxyvinyl polymer, an alkyl-modified carboxyvinyl polymer, polyacrylic acid, an acrylic acid/alkyl methacrylate copolymer, polyethylene glycol, a (hydroxyethyl acrylate/sodium acryloyldimethyltaurate) copolymer, an (ammonium acryloyldimethyltaurate/vinyl pyrrolidone) copolymer, chemically modified starch, bentonite, and the like. In a case where the hydrogen bonding functional group has an acidic group such as a carboxyl group, the hydrogen bonding functional group may totally or partially become a salt such as a sodium salt, a potassium salt, or an ammonium salt.

In a case where the thermoelectric conversion layer contains a polymer compound, in view of further improving the performance of the thermoelectric conversion layer, the content of the polymer compound with respect to the total mass of the thermoelectric conversion layer is preferably 0.5% to 50% by mass, more preferably 5% to 45% by mass, and even more preferably 10% to 40% by mass.

The weight-average molecular weight of the polymer compound is preferably 5,000 to 10,000,000, more preferably 10,000 to 5,000,000, and even more preferably 50,000 to 5,000,000. The weight-average molecular weight is measured by gel permeation chromatography (GPC).

For GPC, HLC-8220GPC (manufactured by Tosoh Corporation) is used, TSKgel G5000PW_{XL}, TSKgel G4000PW_{XL}, and TSKgel G2500PW_{XL} (manufactured by Tosoh Corporation, 7.8 mmID×30 cm) are used as columns, and an aqueous 10 mM NaNO₃ solution is used as an eluent. GPC is performed using a refractive index (RI) detector under the conditions of a sample concentration of 0.1% by mass, a flow rate of 1.0 ml/min (reference=0.5 ml/min), a sample injection amount of 100 μl, and a measurement temperature of 40° C.

In addition, a calibration curve is created from TSKstandard POLY(ETHYLENE OXIDE): “SE-150”, “SE-30”, “SE-8”, “SE-5”, “SE-2” (manufactured by Tosoh Corporation), polyethylene glycol having a molecular weight of 3,000, and hexaethylene glycol having a molecular weight of 282.

((Dispersant))

A dispersant is not particularly limited as long as it has a function of dispersing the organic thermoelectric conversion material (particularly CNT). It is possible to use any of the dispersants having a low molecular weight and a high molecular weight as long as they have a functional group adsorbed onto the organic thermoelectric conversion material (particularly CNT) (for example, an alkyl group, an aromatic group such as benzene, naphthalene, pyrene, anthracene, terphenylene, and porphyrin, an alicyclic group such as cholesterol, and the like), a steric repulsion group inhibiting the aggregation of the organic thermoelectric conversion material (particularly CNT) (for example, a linear or branched alkyl group, a group derived from a polymer such as a polyacrylic acid ester, and the like), and/or an electrostatic repulsion group (for example, a salt of a carboxyl group, a sulfonic acid group, a phosphoric acid group, and the like, an ammonium group, and the like). Among these, a surfactant is preferably used.

The surfactant is a compound having a portion easily attracted to water (hydrophilic group) and a portion not being easily attracted to water (hydrophobic portion) in a molecule. In the present specification, the surfactant may be a low-molecular weight compound (compound having a molecular weight equal to or smaller than 1,000) or a polymer compound having a predetermined repeating unit.

The type of the surfactant is not particularly limited, and known surfactants can be used as long as they have a function of dispersing the organic thermoelectric conversion material (particularly CNT). More specifically, as the surfactant, various surfactants can be used as long as they are dissolved in water, a polar solvent, or a mixture of water and a polar solvent and adsorbed onto the organic thermoelectric conversion material (particularly CNT).

Examples of the surfactant include an ionic surfactant (an anionic surfactant, a cationic surfactant, and an amphoteric surfactant), a nonionic surfactant, and the like. Among these, an ionic surfactant is preferable, and an anionic surfactant is more preferable, because these surfactants excellently disperse CNT, improve the thermoelectric conversion performance of the thermoelectric conversion layer, and are easily removed by washing.

Examples of the anionic surfactant include fatty acid salts, abietates, hydroxyalkanesulfonates, alkanesulfonates, an aromatic sulfonic acid-based surfactant, dialkylsulfosuccinates, linear alkyl benzene sulfonates, branched alkyl benzene sulfonates, alkyl naphthalene sulfonates, alkyl phenoxypolyoxyethylene propyl sulfonates, polyoxyethylene alkyl sulfophenyl ether salts, N-methyl-N-oleyltaurine sodiums, N-alkylsulfosuccinic acid monoamide disodium salts, petroleum sulfonates, sulfated castor oil, sulfated beef tallow oil, sulfuric acid ester salts of fatty acid alkyl ester, alkyl sulfuric acid ester salts, polyoxyethylene alkyl ether sulfuric acid ester salts, fatty acid monoglyceride sulfuric acid ester salts, polyoxyethylene alkyl phenyl ether sulfuric acid ester salts, polyoxyethylene styryl phenyl ether sulfuric acid ester salts, alkyl phosphoric acid ester salts, polyoxyethylene alkyl ether phosphoric acid ester salts, polyoxyethylene alkyl phenyl ether phosphoric acid ester salts, partially saponificated substances of styrene-maleic anhydride copolymers, partially saponificated substances of olefin-maleic anhydride copolymers, naphthalene sulfonate formalin condensates, aromatic sulfonates, aromatic substituted polyoxyethylene sulfonates, a monosoap-based anionic surfactant, an ether sulfate-based surfactant, a phosphate-based surfactant, a carboxylic acid-based surfactant, a fatty acid salt, and the like.

More specifically, examples thereof include octylbenzene sulfonate, nonylbenzene sulfonate, dodecyl sulfonate, dodecylbenzene sulfonate, dodecyldiphenylether disulfonate, monoisopropyl naphthalene sulfonate, diisopropyl naphthalene sulfonate, triisopropyl naphthalene sulfonate, dibutyl naphthalene sulfonate, a salt of a naphthalene sulfonate formalin condensate, sodium cholate, potassium cholate, sodium deoxycholate, potassium deoxycholate, sodium glycocholate, sodium lithocholate, cetyl trimethyl ammonium bromide, and the like.

Examples of the cationic surfactant include an alkylamine salt, a quaternary ammonium salt, and the like.

Examples of the amphoteric surfactant include an alkyl betaine-based surfactant, an amine oxide-based surfactant, and the like.

Examples of the nonionic surfactant include a sugar ester-based surfactant such as a sorbitan fatty acid ester and a polyoxyethlyene sorbitan fatty acid ester, a fatty acid ester-based surfactant such as polyoxyethylene resin acid ester and polyoxyethlyene diethyl fatty acid, an ether-based surfactant such as a fatty acid ester of a polyhydric alcohol-type glycerol, a fatty acid ester of pentaerythritol, a fatty acid ester of sorbitol and sorbitan, a fatty acid ester of sucrose, alkylether of a polyhydric alcohol, a fatty acid amide of alkanolamines, polyoxyethylene alkyl ether, polyoxyethylene alkyl phenyl ether, polyethylene glycol, and polypropylene glycol, and an aromatic nonionic surfactant such as polyoxyalkylene octyl phenyl ether, polyoxyalkylene nonyl phenyl ether, polyoxyalkyl dibutyl phenyl ether, polyoxyalkylstyryl phenyl ether, polyoxyalkylbenzyl phenyl ether, polyoxyalkyl bisphenyl ether, and polyoxyalkyl cumyl phenyl ether.

As the nonionic surfactant, a so-called water-soluble polymer can also be used. For example, polyvinyl alcohol, polyvinylpyrrolidone, a sugar polymer such as amylose, cycloamylose, and chitosan, and the like can also be used.

Among the above surfactants, an ionic surfactant is preferable, and an anionic surfactant is more preferable. Particularly, cholate and deoxycholate are even more suitably used.

In a case where an ionic surfactant, particularly, cholate and deoxycholate are used as a surfactant, it is possible to excellently disperse CNT in a dispersion composition. As a result, it is possible to form a thermoelectric conversion layer containing a large number of long CNTs with few defects, and accordingly, a thermoelectric conversion element having excellent thermoelectric conversion performance can be obtained.

In addition, because such a surfactant can disperse CNTs at a high concentration, it is easy to obtain a thick thermoelectric conversion layer. As a result, a high thermoelectric conversion performance can be obtained.

In a case where the thermoelectric conversion layer contains a dispersant, it is preferable that the content of the dispersant is small. Specifically, the content of the dispersant with respect to the total mass of the thermoelectric conversion layer is preferably 0% to 50% by mass, more preferably 0% to 10% by mass, and even more preferably 0% to 5% by mass.

((Other Components))

The thermoelectric conversion layer may contain an antifoaming agent, an anti-drying agent, a fungicide, and the like, in addition to the aforementioned components.

From the viewpoint of causing a temperature difference, the average thickness of the thermoelectric conversion layer is preferably 0.1 to 1,000 μm and more preferably 1 to 100 μm.

The average thickness of the thermoelectric conversion layer is determined by measuring the thickness of the thermoelectric conversion layer at ten random points and calculating the arithmetic mean thereof.

(Method for Forming Thermoelectric Conversion Layer)

The method for forming the thermoelectric conversion layer is not particularly limited. For example, the thermoelectric conversion layer can be formed by a method of using a dispersion liquid which is obtained by dissolving or dispersing an organic thermoelectric conversion material, a dopant, and components such as a polymer compound and a dispersant, which are added if necessary, in a solvent such as water or an organic solvent.

For instance, by coating a substrate having electrodes and a buffer layer, which will be described later, with the aforementioned dispersion liquid so as to form a film, the thermoelectric conversion layer can be formed.

The method for forming a film as the thermoelectric conversion layer is not particularly limited. As the method, it is possible to use known coating methods such as a spin coating method, an extrusion die coating method, a blade coating method, a bar coating method, a screen printing method, a metal mask printing method, a stencil printing method, a roll coating method, a curtain coating method, a spray coating method, a dip coating method, and an ink jet method.

In a case where the thermoelectric conversion layer is prepared at a predetermined position, it is possible to use a method of coating the substrate with the dispersion liquid in a pattern shape.

One of the examples of the method of coating the substrate with the dispersion liquid in a pattern shape includes a method of patternwise printing the dispersion liquid on the substrate by a printing method. As the printing method, it is possible to use various known printing methods such as screen printing, metal mask printing, gravure printing, flexographic printing, and offset printing.

Furthermore, it is possible to use a method of providing a mold or a mask on the substrate at a predetermined position and coating the substrate with a dispersion liquid or a paste in a pattern shape by using the mold or the mask.

In addition, after the substrate is coated with the dispersion liquid, if necessary, a drying step may be performed. For example, by blowing hot air to the substrate coated with the dispersion liquid, it is possible to volatilize the solvent and dry the thermoelectric conversion layer.

If necessary, after the substrate is coated with the dispersion liquid, a treatment for washing the thermoelectric conversion layer may be performed. Particularly, in a case where a solvent, which can dissolve components (for example, a surfactant and the like) except for the organic thermoelectric conversion material, is used at the time of the washing treatment, it is possible to increase the content of the organic thermoelectric conversion material in the thermoelectric conversion layer and to further improve the performance of the thermoelectric conversion element.

Furthermore, instead of the method of coating the substrate with a dispersion liquid or the like in a pattern shape, a method can be used in which a thermoelectric conversion layer is formed by coating the entire surface of the substrate with the dispersion liquid and drying the dispersion liquid, and then unnecessary portions are removed from the thermoelectric conversion layer by laser engraving, a sand blasting method, an electron beam method, and etching such as plasma etching so as to pattern the thermoelectric conversion layer.

Etching can be performed using, if necessary, a mask, which is formed by photolithography, a metal mask, and the like.

<Buffer Layer>

The buffer layer is a layer which is disposed between the aforementioned thermoelectric conversion layer and each of the aforementioned electrodes and electrically connects the thermoelectric conversion layer and each of the electrodes to each other. In a case where the buffer layer is provided, the thermoelectric conversion layer and the electrodes do not come into contact with each other. Accordingly, the corrosion of the electrodes caused by the dopant contained in the thermoelectric conversion layer is inhibited.

(Component Contained in Buffer Layer)

The buffer layer contains the same material as the organic thermoelectric conversion material contained in the thermoelectric conversion layer. Furthermore, the buffer layer does not contain a dopant or contains a dopant. In a case where the buffer layer contains a dopant, a ratio of the dopant contained in the buffer layer to the dopant contained in the thermoelectric conversion layer is equal to or lower than 0.1.

Hereinafter, the components contained in the buffer layer and components that can be contained in the buffer layer will be described.

((Organic Thermoelectric Conversion Material))

The buffer layer contains the same material as the organic thermoelectric conversion material contained in the thermoelectric conversion layer, and consequently, the thermoelectric conversion performance of the thermoelectric conversion element can be improved.

Because the buffer layer and the thermoelectric conversion layer contain the same organic thermoelectric conversion material, the adhesiveness between the buffer layer and the thermoelectric conversion layer becomes excellent.

The organic thermoelectric conversion material contained in the buffer layer is as described above in the section of the thermoelectric conversion layer, and a preferred aspect thereof is also the same. Therefore, the organic thermoelectric conversion material contained in the buffer layer will not be described.

The content of the organic thermoelectric conversion material in the buffer layer with respect to the total mass of the buffer layer is preferably 50% to 100% by mass, more preferably 50% to 90% by mass, and even more preferably 50% to 80% by mass.

((Dopant))

The buffer layer does not contain a dopant or contains a dopant. In a case where the buffer layer contains a dopant, a ratio of the dopant contained in the buffer layer to the dopant contained in the thermoelectric conversion layer is equal to or lower than 0.1. In this case, the corrosion of the electrodes can be inhibited.

In a case where the buffer layer contains a dopant, the ratio of the dopant contained in the buffer layer to the dopant contained in the thermoelectric conversion layer is calculated based on a value measured using time-of-flight secondary ion mass spectrometry (TOF-SIMS).

In the time-of-flight secondary ion mass spectrometry (TOF-SIMS), from the mass number of secondary ions in each of the thermoelectric conversion layer and the buffer layer, a mass ratio of the dopant in each layer is measured, and the mass ratio of the dopant in the buffer layer is divided by the mass ratio of the dopant in the thermoelectric conversion layer so as to calculate a value (dopant ratio). In a case where the thermoelectric conversion layer and the buffer layer are not exposed on the surface, by performing cutting or the like so as to make the thermoelectric conversion layer and the buffer layer exposed on the surface, the mass ratio of the dopant can be measured.

It is preferable that the buffer layer substantially does not contain a dopant, and in this case, the corrosion of the electrode can be further inhibited.

Herein, “substantially does not contain a dopant” means that a dopant is intentionally not added at the time of preparing a composition (dispersion liquid) used for forming the buffer layer and at the time of manufacturing the buffer layer, and a buffer layer containing a dopant which is inevitably mixed in at the time of preparing the composition and at the time of manufacturing the buffer layer is regarded as the buffer layer which substantially does not contain a dopant. More specifically, in a case where the buffer layer “substantially does not contain a dopant”, the ratio of the dopant contained in the buffer layer to the dopant contained in the thermoelectric conversion layer is preferably equal to or lower than 0.05, more preferably equal to or lower than 0.01, and even more preferably 0 (that is, the buffer layer even more preferably does not contain a dopant).

In a case where the buffer layer contains a dopant, the dopant contained in the buffer layer is as described above in the section of the thermoelectric conversion layer. Therefore, the dopant contained in the buffer layer will not be described.

((Polymer Compound))

As described above, in the present invention, it is preferable that at least one of the thermoelectric conversion material or the buffer layer, which will be described later, contains a polymer compound.

In a case where the buffer layer contains a polymer compound, the same effect as the effect described above in a case where the thermoelectric conversion layer contains a polymer compound is exerted.

In a case where the buffer layer contains a polymer compound, the polymer compound contained in the buffer layer is as described above in the section of the thermoelectric conversion layer, and a preferred aspect thereof is also the same. Therefore, the polymer compound contained in the buffer layer will not be described.

The buffer layer may contain the dispersant described above in the section of the thermoelectric conversion layer and other components. Each of these components is as described above in the section of the thermoelectric conversion layer, and a preferred aspect thereof is also the same. Therefore, those components will not be described.

(Method for Forming Buffer Layer)

The method for forming the buffer layer is not particularly limited. For example, it is possible to use a method of using a dispersion liquid which is obtained by dissolving or dispersing an organic thermoelectric conversion material and components such as a polymer compound and a dispersant, which are added if necessary, in a solvent such as water or an organic solvent.

For instance, by coating a substrate having electrodes with the aforementioned dispersion liquid so as to form a film, the buffer layer can be formed.

The method for forming a film as the buffer layer is not particularly limited, and the buffer layer can be formed by the same method as the aforementioned method for forming the thermoelectric conversion layer.

Herein, it is preferable that a step of forming the thermoelectric conversion layer and a step of forming the buffer layer are simultaneously performed. In this case, the two layers can be simultaneously formed, and accordingly, the manufacturing efficiency can be further improved than in a case where the two layers are separately formed. The method for simultaneously forming the two layers is not particularly limited, and examples thereof include a method of simultaneously coating the substrate with the dispersion liquid used for forming the thermoelectric conversion layer and the dispersion liquid used for forming the buffer layer by using a slit coater or the like.

<Protective Substrate>

The protective substrate is a substrate disposed on the thermoelectric conversion layer, and protects the thermoelectric conversion layer from the outside. The protective substrate may be disposed if necessary.

The type of the protective substrate is not particularly limited. In view of the bending resistance of the thermoelectric conversion element, a resin substrate is preferable. Specific examples of the resin substrate include the aforementioned specific examples of the resin substrate used as a substrate.

### Second Embodiment

FIG. 2 is a view conceptually showing a thermoelectric conversion element of a second embodiment that is an example of the thermoelectric conversion element of the present invention.

As shown in FIG. 2, a thermoelectric conversion element 1B is an element having a substrate 2, a first electrode 3B, a first buffer layer 8B, a thermoelectric conversion layer 5, a second buffer layer 9B, a second electrode 4B, and a protective substrate 6 in this order. The thermoelectric conversion element 1B shown in FIG. 2 is an aspect in which an electromotive force (voltage) is obtained using a temperature difference caused in the direction indicated by the arrow.

As shown in FIG. 2, each of the first buffer layer 8B and the second buffer layer 9B is disposed between the thermoelectric conversion layer 5 and the electrode (the first electrode 3B and the second electrode 4B) and electrically connects the thermoelectric conversion layer 5 and the electrode to each other. That is, each of the buffer layers is disposed between the thermoelectric conversion layer and the electrode such that the thermoelectric conversion layer and the electrode do not come into direct contact with each other.

In the thermoelectric conversion element 1B as the second embodiment, the same members as those in the thermoelectric conversion element 1A of the first embodiment are used, but the disposition positions thereof are different. Specifically, the thermoelectric conversion layer 5 is interposed between the first buffer layer 8B (first electrode 3B) and the second buffer layer 9B (second electrode 3B) in a direction perpendicular to the substrate surface.

The first electrode 3B and the second electrode 4B are members constituted with the same material as the first electrode 3A and the second electrode 4A described above. Furthermore, the first buffer layer 8B and the second buffer layer 9B are members constituted with the same material as the first buffer layer 8A and the second buffer layer 9A described above.

### Third Embodiment

FIG. 3 is a view conceptually showing a thermoelectric conversion element of a third embodiment that is an example of the thermoelectric conversion element of the present invention.

As shown in FIG. 3, a thermoelectric conversion element 1C has a substrate 2, a thermoelectric conversion layer 5 disposed on the substrate 2, a first buffer layer 8C disposed on a portion of the top surface and one lateral surface of the thermoelectric conversion layer 5, a second buffer layer 9C disposed on a portion of the top surface and the other lateral surface of the thermoelectric conversion layer 5, a first electrode 3C disposed on the top surface and a lateral surface of the first buffer layer 8C, and a second electrode 4C disposed on the top surface and a lateral surface of the second buffer layer 9C. The thermoelectric conversion element 1C shown in FIG. 3 is an aspect in which an electromotive force (voltage) is obtained by using a temperature difference caused in the direction indicated by the arrow.

More specifically, the first buffer layer 8C and the second buffer layer 9C are disposed on the substrate 2 at positions spaced apart from each other.

Furthermore, the first electrode 3C and the second electrode 4C are disposed on the substrate 2 at positions spaced apart from each other. In addition, the first electrode 3C is electrically connected to the thermoelectric conversion layer 5 through the first buffer layer 8C, and the second electrode 4C is electrically connected to the thermoelectric conversion layer 5 through the second buffer layer 9C.

That is, each of the buffer layers is disposed between the thermoelectric conversion layer and the electrode such that the thermoelectric conversion layer and the electrodes do not come into direct contact with each other.

In the thermoelectric conversion element 1C as the third embodiment, the same members as those in the thermoelectric conversion element 1A of the first embodiment are used, but the disposition positions thereof are different. Specifically, the thermoelectric conversion layer 5 is interposed between the first buffer layer 8C (first electrode 3C) and the second buffer layer 9C (second electrode 4C) in a direction parallel to the substrate surface.

Furthermore, although the thermoelectric conversion element 1C of the third embodiment does not have a protective substrate, a protective substrate may be provided, for example, at a position covering at least the exposed portion of the top surface of the thermoelectric conversion layer 5 (region where the electrode and the buffer layers are not formed).

The first electrode 3C and the second electrode 4C are members constituted with the same material as the first electrode 3A and the second electrode 4A described above. In addition, the first buffer layer 8C and the second buffer layer 9C are members constituted with the same material as the first buffer layer 8A and the second buffer layer 9A described above.

### Fourth Embodiment

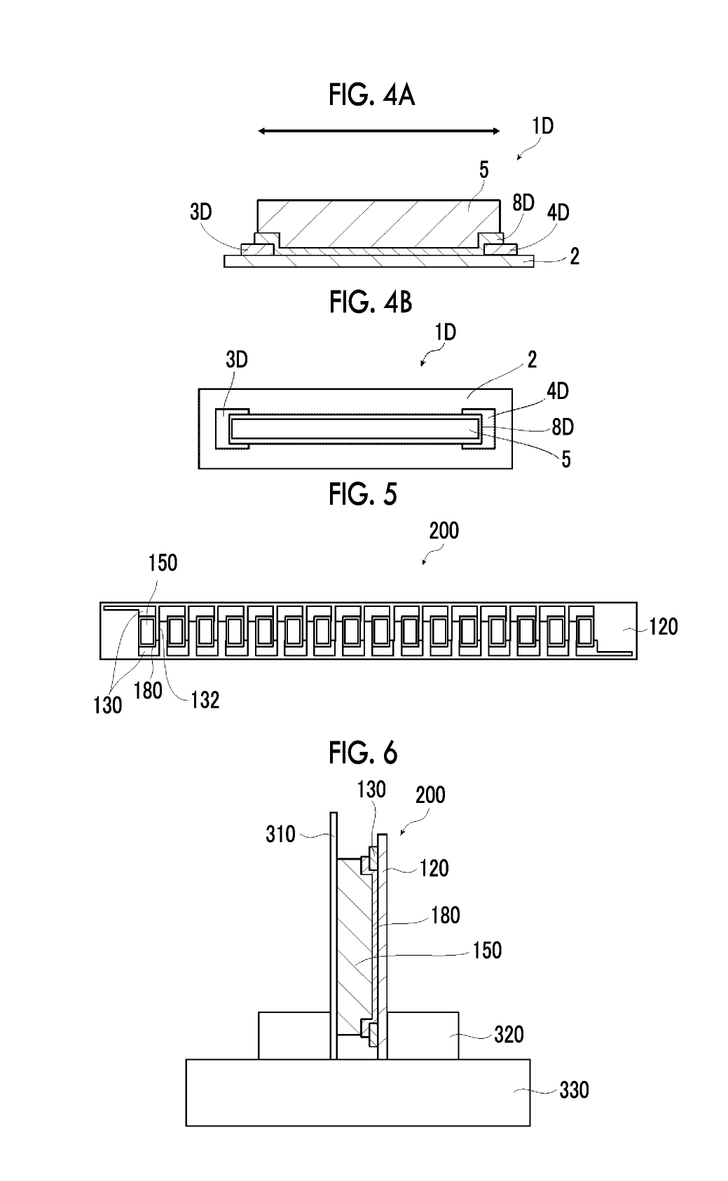

FIGS. 4A and 4B are views conceptually showing a thermoelectric conversion element of a fourth embodiment that is an example of the thermoelectric conversion element of the present invention. FIG. 4A is a lateral cross-sectional view of a thermoelectric conversion element 1D of the fourth embodiment, and FIG. 4B is a top view of the thermoelectric conversion element 1D of the fourth embodiment. Hereinbelow, FIGS. 4A and 4B will be collectively called FIG. 4 in some cases.

As shown in FIG. 4, the thermoelectric conversion element 1D has a substrate 2, a first electrode 3D and a second electrode 4D disposed on the substrate 2 at positions spaced apart from each other, a buffer layer 8D disposed on the substrate 2 so as to come into contact with the first electrode 3D and the second electrode 4D, and a thermoelectric conversion layer 5 disposed on the substrate so as to come into contact with the buffer layer 8D. The thermoelectric conversion element 1D shown in FIG. 4 is an aspect in which an electromotive force (voltage) is obtained using a temperature difference caused in the direction indicated by the arrow.

As shown in FIG. 4, the buffer layer 8D is disposed between the thermoelectric conversion layer 5 and the electrode (the first electrode 3D and the second electrode 4D) and electrically connects the thermoelectric conversion layer 5 and the electrode to each other. That is, the buffer layer is disposed between the thermoelectric conversion layer and the electrode such that the thermoelectric conversion layer and the electrode do not come into direct contact with each other.

In the thermoelectric conversion element 1D as the fourth embodiment, the same members as those in the thermoelectric conversion element 1A of the first embodiment are used, but the thermoelectric conversion element 1D is different from the thermoelectric conversion element 1A of the first embodiment in terms of the following points.

While the thermoelectric conversion layer 5 in the fourth embodiment does not come into contact with the substrate 2, the thermoelectric conversion layer 5 in the first embodiment comes into contact with the substrate 2. In this way, there is a difference in the disposition position of the thermoelectric conversion layer between the fourth embodiment and the first embodiment.

Furthermore, in the fourth embodiment, only one buffer layer 8D is provided, and the buffer layer 8D comes into contact with the top of both the first electrode 3D and the second electrode 4D. In contrast, in the first embodiment, two buffer layers (the first buffer layer 8A and the second buffer layer 9A) are provided which are disposed at positions spaced apart from each other, the first buffer layer 8A comes into contact with the top of the first electrode 3A, and the second buffer layer 9A comes into contact with the top of the second electrode 4A. In this way, there is a difference in the number of buffer layers between the fourth embodiment and the first embodiment.

In addition, although the thermoelectric conversion element 1D of the fourth embodiment does not have a protective substrate, a protective substrate may be provided, for example, at a position covering the top surface of the thermoelectric conversion layer 5.

The first electrode 3D and the second electrode 4D are members constituted with the same material as the first electrode 3A and the second electrode 4A described above. Furthermore, the buffer layer 8D is a member constituted with the same material as the first buffer layer 8A and the second buffer layer 9A described above.

<Thermoelectric Conversion Module>

The thermoelectric conversion module of the present invention has a plurality of thermoelectric conversion elements of the present invention. The thermoelectric conversion module of the present invention can be applied to various aspects. For example, the module can be applied to an aspect in which a buffer layer is provided between a thermoelectric conversion layer and an electrode in the thermoelectric conversion module shown in FIG. 4 in WO2015/098574A, an aspect in which a buffer layer is provided between an electrode and a thermoelectric conversion layer in the thermoelectric conversion module having a wavy structure shown in FIG. 17 in WO2013/114854A, an aspect of a thermoelectric conversion module shown in FIG. 5 which will be described later, and the like.

(Method for Manufacturing Thermoelectric Conversion Module)

Hereinbelow, as an aspect of the method for manufacturing a thermoelectric conversion module of the present invention, an example of the method for manufacturing a thermoelectric conversion module 200 shown in FIG. 5 will be described, but the method for manufacturing a thermoelectric conversion module is not limited thereto.

First, an electrode forming material is printed on a substrate 120, and the printed electrode forming material is dried, thereby forming a plurality of electrodes 130. The electrodes 130 can be formed, for example, by the method forming an electrode described above in the first embodiment. Furthermore, the electrodes 130 are connected to each other through wiring 132 such that a plurality of thermoelectric conversion layers 150, which will be described later, are connected to in series. The method for forming the silver wiring 132 is not particularly limited, and known methods can be used. In a case where the electrodes 130 and the wiring 132 are formed of the same material, the electrodes and the wiring may be formed simultaneously.

Thereafter, buffer layers 180 are formed on the electrodes 130. Each of the buffer layers 180 is formed at a position where thermoelectric conversion layers 150, which will be formed next, and the electrodes 130 do not come into contact with each other but are electrically connected to each other. In the example shown in FIG. 5, a plurality of buffer layers 180 are formed at positions corresponding to the plurality of electrodes 130 respectively. The buffer layers 180 can be formed, for example, by the method for forming a buffer layer described above in the first embodiment.

Subsequently, the thermoelectric conversion layers 150 are formed on the buffer layers 180. The thermoelectric conversion layers 150 are electrically connected to the electrodes 130 through the buffer layers 180. In the example shown in FIG. 5, a plurality of thermoelectric conversion layers 150 are formed at positions corresponding to the plurality of buffer layers 180 respectively. The thermoelectric conversion layers 150 are formed, for example, by the method for forming a thermoelectric conversion layer described above in the first embodiment.

In this way, the thermoelectric conversion module 200 is obtained.

In manufacturing the thermoelectric conversion module, it is preferable that the step of forming the thermoelectric conversion layer and the step of forming the buffer layer are performed simultaneously. In this case, the two layers (the thermoelectric conversion layer and the buffer layer) can be formed simultaneously, and accordingly, the manufacturing efficiency can be further improved than in a case where the two layers are separately formed. The method for simultaneously forming the two layers is not particularly limited, and examples thereof include a method of simultaneously coating the substrate with a dispersion liquid used for forming the thermoelectric conversion layer and a dispersion liquid used for forming the buffer layer by using a slit coater or the like.

The thermoelectric conversion element and the thermoelectric conversion module of the present invention can be used for various uses.

For example, the thermoelectric conversion element and the thermoelectric conversion module can be used for various types of power generation including a power generator such as a hot spring heat power generator, a solar power generator, and a waste heat power generator, a power supply for a wrist watch, a power supply for various devices such as a power supply for driving a semiconductor, a power supply for a small sensor, and the like. As the use of the thermoelectric conversion element of the present invention, in addition to the power generation use, sensor element uses such as a thermal sensor and a thermocouple can be exemplified.

Hitherto, the thermoelectric conversion element and the thermoelectric conversion module of the present invention have been specifically described. However, the present invention is not limited to the above examples, and it goes without saying that various types of amelioration or modification may be carried out within a scope that does not depart from the gist of the present invention.

### EXAMPLES

Hereinafter, the present invention will be specifically described using examples, but the present invention is not limited thereto.

### Examples 1 to 26 and Comparative Examples 1 to 5

By using a thermoelectric conversion element and a thermoelectric conversion module of Comparative Example 1 as standard comparative examples, thermoelectric conversion elements and thermoelectric conversion modules of Examples 1 to 26 and Comparative Examples 1 to 5 were evaluated in terms of various items.

### Example 1

(Pre-Treatment)

By using a mechanical homogenizer (manufactured by SMT Corporation, HIGH-FLEX HOMOGENiZER HF93), 500 mg of single-layer CNT (Tuball manufactured by OCSiAl) and 250 mL of acetone were mixed together for 5 minutes at 18,000 rpm, thereby obtaining a dispersion liquid. The dispersion liquid was filtered under reduced pressure by using a Buchner funnel and a suction bottle, thereby obtaining a cloth-like CNT film (buckypaper). The cloth-like CNT film was cut in a size of about 3.5 mm×3.5 mm and used for the preparation of a dispersion liquid 1A as the next step.

(Preparation of Dispersion Liquid 1A)

As a pre-treatment, 1,200 mg of sodium deoxycholate (manufactured by TOKYO CHEMICAL INDUSTRY CO., LTD.) was dissolved in 16 mL of water, and 400 mg of CNT cut in a size of about 3.5 mm×3.5 mm was added to the obtained solution, thereby obtaining a composition. The composition was mixed for 7 minutes by using a mechanical homogenizer (manufactured by SMT Corporation, HIGH-FLEX HOMOGENiZER HF93), thereby obtaining a premix. By using a thin film revolution-type high-speed mixer “FILMIX 40-40 model” (manufactured by PRIMIX Corporation), a dispersion treatment was performed on the obtained premix and 200 mg of tetracyanoquinodimethane (manufactured by Wako Pure Chemical Industries, Ltd.) in a constant-temperature tank with a temperature of 10° C. for 2 minutes at a circumferential speed of 10 m/sec and then for 5 minutes at a circumferential speed of 40 m/sec. By using a rotation-revolution mixer (manufactured by THINKY CORPORATION, AWATORI RENTARO), the obtained dispersion composition was mixed for 30 seconds at 2,000 rpm and then defoamed for 30 seconds at 2,200 rpm, thereby preparing a dispersion liquid 1A.

The oxidation-reduction potential of tetracyanoquinodimethane (TCNQ) with respect to a saturated calomel reference electrode is 0.15 V.

(Preparation of Dispersion Liquid 1B)

A dispersion liquid 1B was prepared in the same manner as that used for preparing the dispersion liquid 1A, except that tetracyanoquinodimethane was not added.

(Manufacturing of Thermoelectric Conversion Element)

Hereinbelow, the method for manufacturing a thermoelectric conversion element (thermoelectric conversion element 1D) of Example 1 will be described with reference to FIG. 4.

First, on the substrate 2 (polyimide substrate), two silver pastes (manufactured by FUJIKURA KASEI CO., LTD.) were printed in a size of 2 cm×2 cm at an interval of 10 cm by screen printing, and the printed materials of the silver pastes were dried for 1 hour at 110° C., thereby forming the first electrode 3D and the second electrode 4D.

Then, by metal mask printing, the dispersion liquid 1B was printed in a size of 1.5 cm (width)×12 cm (length) on the first electrode 3D and the second electrode 4D, thereby obtaining a printed material of the dispersion liquid 1B. The printed material of the dispersion liquid 1B was formed such that the ends of the first electrode 3D and the second electrode 4D were covered. Thereafter, the printed material of the dispersion liquid 1B was dried for 30 minutes at 50° C. and then for 30 minutes at 120° C., and then immersed in ethanol for 1 hour so as to remove the dispersant in the printed material of the dispersion liquid 1B, thereby forming the buffer layer 8D.

Subsequently, by metal mask printing, the dispersion liquid 1A was printed in a size of 1 cm (width)×11 cm (length) on the buffer layer 8D, thereby obtaining a printed material of the dispersion liquid 1A. The printed material of the dispersion liquid 1A was printed on a position which was in the region where the buffer layer 8D was formed and the first electrode 3D and the second electrode 4D were connected to each other through the buffer layer 8D. The printed material of the dispersion liquid 1A was dried for 30 minutes at 50° C. and then for 30 minutes at 120° C. and then immersed in ethanol for 1 hour so as to remove the dispersant in the printed material of the dispersion liquid 1A, thereby obtaining the thermoelectric conversion layer 5. In this way, a laminate was obtained in which the substrate 2, the first electrode 3D and the second electrode 4D, the buffer layer 8D, and the thermoelectric conversion layer 5 were laminated in this order.

The laminate was dried for 30 minutes at 50° C. and then for 150 minutes at 120° C., thereby obtaining a thermoelectric conversion element 1D. The thermoelectric conversion element 1D obtained in this way was used as a thermoelectric conversion element of Example 1.

(Manufacturing of Thermoelectric Conversion Module)

FIG. 5 is a top view schematically showing the structure of the thermoelectric conversion module 200 used in each of the examples and the comparative examples.

Hereinbelow, the method for manufacturing a thermoelectric conversion module (thermoelectric conversion module 200) of Example 1 will be described.

First, on the substrate 120 (polyimide substrate) having a size of 1.6 cm (width)×14 cm (length), a silver paste was printed by screen printing. The printed material of the silver paste was dried for 1 hour at 120° C., thereby simultaneously forming seventeen pairs of electrodes 130 and the wiring 132. Each of the electrodes has a size of 4 mm (width)×2.5 mm (length), and the distance between the electrodes is 5 mm. Furthermore, each pair of electrodes 130 are connected to each other through the wiring 132 having a width of 1 mm such that seventeen thermoelectric conversion layers 150, which will be described later, are connected to each other in series.

Then, by metal mask printing, the dispersion liquid 1B was printed in a size of 4 mm (width)×8 mm (length) on the electrodes 130, thereby obtaining printed materials of the dispersion liquid 1B. Seventeen printed materials of the dispersion liquid 1B were formed such that the ends of one pair of electrode 130 were covered. Thereafter, the printed materials of the dispersion liquid 1B were dried for 30 minutes at 50° C. and then for 30 minutes at 120° C., and then immersed in ethanol for 1 hour so as to remove the dispersant, thereby forming seventeen buffer layers 180.

Subsequently, by metal mask printing, the dispersion liquid 1A was printed in a size of 3 mm (width)×6 mm (length) on the buffer layers 180, thereby obtaining printed materials of the dispersion liquid 1A. Seventeen printed materials of the dispersion liquid 1A were formed at positions which were in a region where the buffer layers 180 were formed and connected each pair of electrodes 130 through each of the buffer layers 180.

The printed materials of the dispersion liquid 1A were dried for 30 minutes at 50° C. and then for 30 minutes at 120° C., and then immersed in ethanol for 1 hour so as to remove the dispersant in the printed materials of the dispersion liquid 1A, thereby obtaining thermoelectric conversion layers 150. In this way, seventeen laminates were obtained in which the substrate 120, the electrode 130, the buffer layer 180, and the thermoelectric conversion layer 150 were laminated in this order.

The laminate was dried for 30 minutes at 50° C. and then for 150 minutes at 120° C., thereby obtaining the thermoelectric conversion module 200. The thermoelectric conversion module 200 obtained in this way was used as a thermoelectric conversion module of Example 1.

### Example 2

In the preparation of the dispersion liquid 1A, 100 mg of sodium carboxymethyl cellulose (low-viscosity product, manufactured by Sigma-Aldrich Co. LLC.) was further added, thereby preparing a dispersion liquid 2A. Then, a thermoelectric conversion element and a thermoelectric conversion module of Example 2 were obtained in the same manner as that in Example 1, except that the dispersion liquid 2A was used instead of the dispersion liquid 1A.

### Example 3

In the preparation of the dispersion liquid 1B, 100 mg of sodium carboxymethyl cellulose (low-viscosity product, manufactured by Sigma-Aldrich Co. LLC.) was further added, thereby preparing a dispersion liquid 3B. A thermoelectric conversion element and a thermoelectric conversion module of Example 3 were obtained in the same manner as that in Example 1, except that the dispersion liquid 3B was used instead of the dispersion liquid 1B.

### Example 4

A thermoelectric conversion element and a thermoelectric conversion module of Example 4 were obtained in the same manner as that in Example 1, except that the dispersion liquid 2A was used instead of the dispersion liquid 1A, and the dispersion liquid 3B was used instead of the dispersion liquid 1B.

### Example 5

A thermoelectric conversion element and a thermoelectric conversion module of Example 5 were obtained in the same manner as that in Example 4, except that tetracyanoquinodimethane was replaced with tetrafluorotetracyanoquinodimethane (in the present specification, abbreviated to “F4-TCNQ” in some cases), and sodium carboxymethyl cellulose was replaced with guar gum.

The oxidation-reduction potential of the tetrafluorotetracyanoquinodimethane with respect to a saturated calomel reference electrode is 0.52 V.

### Example 6

A thermoelectric conversion element and a thermoelectric conversion module of Example 6 were obtained in the same manner as that in Example 4, except that tetracyanoquinodimethane was replaced with 2,3-dichloro-5,6-dicyano-p-benzoquinone (in the present specification, abbreviated to “DDQ” in some cases), and sodium carboxymethyl cellulose was replaced with sodium alginate.

The oxidation-reduction potential of 2,3-dichloro-5,6-dicyano-p-benzoquinone with respect to a saturated calomel reference electrode is 0.50 V.

### Example 7

A thermoelectric conversion element and a thermoelectric conversion module of Example 7 were obtained in the same manner as that in Example 4, except that tetracyanoquinodimethane was replaced with benzoquinone (in the present specification, abbreviated to “BQ” in some cases).

The oxidation-reduction potential of benzoquinone with respect to a saturated calomel reference electrode is −0.35 V.

### Examples 8 to 24

Thermoelectric conversion elements and thermoelectric conversion modules of Examples 8 to 24 were obtained in the same manner as that in Example 4, except that 200 mg of tetracyanoquinodimethane was replaced with the dopant described in Table 1.

In Example 19, 100 mg of alginic acid was used. In Example 22, 100 mg of polystyrene sulfonic acid was used. In Example 23, 50 mg of iron (III) p-toluenesulfonate was used. In Example 24, 50 mg of iron (III) chloride was used.

In Table 1, pKa of a dopant shown in a parenthesis is a value inferred from pKa of an acid having a structure similar to that of the dopant, and expressed as a range.

### Example 25

(Preparation of Dispersion Liquid 25A)

Poly(3-hexylthiophene) (600 mg, hereinafter, abbreviated to “P3HT” as well) was dissolved in 16 mL of chlorobenzene. This solution was pre-treated in the same manner as that in the preparation of the dispersion liquid 1A in Example 1. Then, 200 mg of single-layer CNT (Tuball manufactured by OCSiAl) cut in a size of about 3.5 mm×3.5 mm was added thereto, thereby obtaining a composition. The composition was mixed for 7 minutes by using a mechanical homogenizer (manufactured by SMT Corporation, HIGH-FLEX HOMOGENiZER HF93), thereby obtaining a premix. By using a thin film revolution-type high-speed mixer “FILMIX 40-40 model” (manufactured by PRIMIX Corporation), a dispersion treatment was performed on the obtained premix in a constant-temperature tank with a temperature of 10° C. for 2 minutes at a circumferential speed of 10 m/sec and then for 5 minutes at a circumferential speed of 40 m/sec, thereby obtaining a dispersion composition. A dopant 1 (200 mg, see Formula (D-1), a triaryl sulfonium salt, a photoacid generator) was added to the obtained dispersion composition, and by using a rotation-revolution mixer (manufactured by THINKY CORPORATION, AWATORI RENTARO), the dispersion composition was mixed for 30 seconds at 2,000 rpm and then defoamed for 30 seconds at 2,200 rpm, thereby preparing a dispersion liquid 25A.

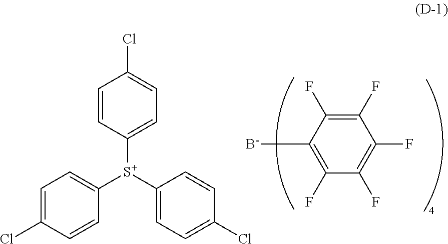

(Preparation of Dispersion Liquid 25B)

A dispersion liquid 25B was prepared in the same manner as that used for preparing the dispersion liquid 25A, except that a photoacid generator (the dopant 1) was not added.

(Manufacturing of Thermoelectric Conversion Element)

A thermoelectric conversion element of Example 25 was prepared as below. The structure of the thermoelectric conversion element of Example 25 is the same as that of the thermoelectric conversion element 1D (see FIGS. 4A and 4B) described in Example 1. Therefore, the method for manufacturing the thermoelectric conversion element of Example 25 will be described by giving the same references as those in the thermoelectric conversion element 1D.

First, on the substrate 2 (polyimide substrate), two silver pastes (manufactured by FUJIKURA KASEI CO., LTD.) were printed in a size of 2 cm×2 cm at an interval of 10 cm by screen printing, and the printed materials of the silver pastes were dried for 1 hour at 110° C., thereby forming the first electrode 3D and the second electrode 4D.

Then, by metal mask printing, the dispersion liquid 25B was printed in a size of 1.5 cm (width)×12 cm (length) on the first electrode 3D and the second electrode 4D, thereby obtaining printed materials of the dispersion liquid 25B. The printed materials of the dispersion liquid 25B were formed such that the ends of the first electrode 3D and the second electrode 4D were covered. Thereafter, the printed materials of the dispersion liquid 25B were dried for 30 minutes at 50° C. and then for 150 minutes at 160° C., thereby forming the buffer layers 8D.

Subsequently, by metal mask printing, the dispersion liquid 25A was printed in a size of 1 cm (width)×11 cm (length) on the buffer layers 8D, thereby obtaining printed materials of the dispersion liquid 25A. The printed materials of the dispersion liquid 25A were printed on positions which were in the region where the buffer layers 8D were formed and the first electrode 3D and the second electrode 4D were connected to each other through the buffer layers 8D. The printed materials of the dispersion liquid 25A were dried for 30 minutes at 50° C. and then for 150 minutes at 120° C. and then irradiated (amount of light: 1.06 J/cm²) with ultraviolet rays by using an ultraviolet irradiation machine (manufactured by EYE GRAPHICS Co., Ltd., ECS-401GC), thereby obtaining the thermoelectric conversion layers 5 which were doped with a component derived from the acid generator contained in the printed materials of the dispersion liquid 25A. In this way, the thermoelectric conversion element 1D was obtained. The obtained thermoelectric conversion element 1D was used as a thermoelectric conversion element of Example 25.

(Manufacturing of Thermoelectric Conversion Module)

A thermoelectric conversion module of Example 25 was prepared as below. The structure of the thermoelectric conversion module of Example 25 is the same as that of the thermoelectric conversion module 200 (see FIG. 5) described in Example 1. Therefore, the method for manufacturing the thermoelectric conversion module of Example 25 will be described by giving the same references as those in the thermoelectric conversion module 200.

First, on the substrate 120 (polyimide substrate) having a size of 1.6 cm (width)×14 cm (length), a silver paste was printed by screen printing. The printed material of the silver paste was dried for 1 hour at 120° C., thereby forming seventeen pairs of electrodes 130. Each of the electrodes has a size of 3 mm (width)×2.5 mm (length). Furthermore, each pair of electrodes 130 are connected to each other through silver wiring such that seventeen thermoelectric conversion layers 150, which will be described later, are connected to each other in series.

Then, by metal mask printing, the dispersion liquid 25B was printed in a size of 5 mm (width)×8 mm (length) on each pair of electrodes 130, thereby obtaining printed materials of the dispersion liquid 25B. Seventeen printed materials of the dispersion liquid 25B were formed such that the ends of each pair of electrodes 130 were covered. Thereafter, the printed materials of the dispersion liquid 25B were dried for 30 minutes at 50° C. and then for 150 minutes at 160° C., thereby forming seventeen buffer layers 180.

Subsequently, by metal mask printing, the dispersion liquid 25A was printed in a size of 3 mm (width)×6 mm (length) on the buffer layers 180, thereby obtaining printed materials of the dispersion liquid 25A. Seventeen printed materials of the dispersion liquid 25A were formed at positions which were in a region where the buffer layers 180 were formed and connected to each pair of electrodes 130 through each of the buffer layers 180.

The printed materials of the dispersion liquid 25A were dried for 30 minutes at 50° C. and then for 150 minutes at 160° C. Then, the printed materials were irradiated (amount of light: 1.06 J/cm²) with ultraviolet rays by using an ultraviolet irradiation machine (manufactured by EYE GRAPHICS Co., Ltd., ECS-401GC), thereby obtaining the thermoelectric conversion layers 150 which were doped with a component derived from the acid generator contained in the printed materials of the dispersion liquid 25A. In this way, the thermoelectric conversion module 200 in which seventeen thermoelectric conversion elements were connected to each other was obtained. The obtained thermoelectric conversion module 200 was used as a thermoelectric conversion module of Example 25.

### Example 26

A substrate was simultaneously coated with the dispersion liquid 3B for forming a buffer layer and the dispersion liquid 2A for forming a thermoelectric conversion layer by using a slit coater such that an electrode, a buffer layer, and a thermoelectric conversion layer were formed in this order, thereby forming a printed material. The obtained printed material was dried for 30 minutes at 50° C. and then for 30 minutes at 120° C., and then immersed in ethanol for 1 hour so as to remove the dispersant, thereby obtaining a thermoelectric conversion element and a thermoelectric conversion module. Except for the aforementioned methods, the same process as that in Example 4 was performed.

That is, the thermoelectric conversion element and the thermoelectric conversion module of Example 26 were prepared by the same manufacturing method as that in Example 4, except that the buffer layer and the thermoelectric conversion layer were simultaneously formed.

### Comparative Example 1

A thermoelectric conversion element and a thermoelectric conversion module of Comparative Example 1 were obtained in the same manner as that in Example 1, except that a buffer layer was not formed.

### Comparative Example 2

A thermoelectric conversion element and a thermoelectric conversion module of Comparative Example 2 were obtained in the same manner as that in Example 2, except that a buffer layer was not formed.

### Comparative Example 3

By changing the amount of tetracyanoquinodimethane added to 50 mg in the preparation of the dispersion liquid 1A, a dispersion liquid 2B′ was prepared.

A thermoelectric conversion element and a thermoelectric conversion module of Comparative Example 3 were obtained in the same manner as that in Example 1, except that the dispersion liquid 2B′ was used for forming a buffer layer.

### Comparative Example 4

A dispersion liquid C1 was obtained in the same manner as that used for obtaining the dispersion liquid 1A of Example 1, except that carbon nanotubes were replaced with graphite, and tetracyanoquinodimethane was not used.

A thermoelectric conversion element and a thermoelectric conversion module of Comparative Example 4 were obtained in the same manner as that in Example 1, except that the dispersion liquid C1 was used for forming a buffer layer.

### Comparative Example 5

A thermoelectric conversion element and a thermoelectric conversion module of Comparative Example 5 were obtained in the same manner as that in Example 2, except that the buffer layer was replaced with tin oxide (thickness: 200 nm, formed by sputtering).

<Evaluation Test>

(Evaluation of Dopant Ratio)

For the thermoelectric conversion element prepared in each of the examples and the comparative examples, from the secondary ions derived from the dopant in the thermoelectric conversion layer and the dopant (buffer layer) between the thermoelectric conversion layer and the electrode, a value (dopant ratio) was calculated by dividing the mass ratio of the dopant (buffer layer) between the thermoelectric conversion layer and the electrode by the mass ratio of the dopant in the thermoelectric conversion layer by time-of-flight secondary ion mass spectrometry (device name: “TOF-SIMS IV”, manufactured by ION-TOF GmbH). The dopant ratio was evaluated based on the following standards.

A: The dopant ratio was equal to or lower than 0.05.

B: The dopant ratio was higher than 0.05 and equal to or lower than 0.075.

C: The dopant ratio was higher than 0.075 and equal to or lower than 0.1.

D: The dopant ratio was higher than 0.1 and equal to or lower than 0.5.

E: The dopant ratio was higher than 0.5.

(Evaluation of Thermoelectric Conversion Element)

((Electric Conductivity))

By bringing a tester into contact with the electrode pair of the thermoelectric conversion element prepared in each of the examples and the comparative examples, the resistance was measured, and the electric conductivity was calculated by the following equation.

(Electric conductivity)=1/[(Resistance×Cross-sectional area of thermoelectric conversion layer)/Distance between electrodes]

Furthermore, by the following equation, the electric conductivity was normalized and evaluated based on the following standards. Comparative Example 1 was used as a standard comparative example for Examples 1 to 26 and Comparative Examples 1 to 5.

(Normalized electric conductivity)=(Electric conductivity of each of examples and comparative examples)/(Electric conductivity of standard comparative example)

A: The normalized electric conductivity was equal to or higher than 2.0.

B: The normalized electric conductivity was equal to or higher than 1.5 and less than 2.0.

C: The normalized electric conductivity was equal to or higher than 0.8 and less than 1.5.

D: The normalized electric conductivity was less than 0.8.

((Seebeck Coefficient))

One end of the thermoelectric conversion element prepared in each of the examples and the comparative examples was installed on a hot plate with a temperature of 100° C., and the other end thereof was kept at room temperature. In this state, a temperature difference ΔT was caused in the thermoelectric conversion layer. The temperature difference ΔT was calculated using a thermometer installed in the thermoelectric conversion element on the heating side and the side kept at room temperature. A voltage V was measured, and a Seebeck coefficient S (unit: μV/K) was calculated by the following equation.

S=V/ΔT

Furthermore, the Seebeck coefficient was normalized by the following equation and evaluated based on the following standards. Comparative Example 1 was used as a standard comparative example for Examples 1 to 26 and Comparative Examples 1 to 5.

(Normalized Seebeck coefficient)=(Seebeck coefficient of each of examples or comparative examples)/(Seebeck coefficient of standard comparative example)

A: The normalized Seebeck coefficient was equal to or higher than 1.2.

B: The normalized Seebeck coefficient was equal to or higher than 0.8 and less than 1.2.

C: The normalized Seebeck coefficient was less than 0.8.

((Evaluation of Figure of Merit Z of Thermoelectric Conversion))

For calculating a figure of merit Z, a thermal conductivity was calculated by the following equation. The specific heat was measured by DSC (differential scanning calorimetry), and the density was measured using weight and dimensions. The thermal diffusivity was measured using a thermal diffusivity measuring device ai-Phase Mobile 1u (manufactured by ai-Phase Co., Ltd).

(Thermal conductivity)=(Specific heat)×(Density)×(Thermal diffusivity)

Furthermore, the figure of merit Z was calculated by the following equation.

(Figure of merit Z)=[(Electric conductivity)×(Seebeck coefficient)²]/Thermal conductivity

The obtained figure of merit Z was normalized by the following equation, and based on the normalized value, the figure of merit Z was evaluated according to the following standards. Comparative Example 1 was used as a standard comparative example for Examples 1 to 26 and Comparative Examples 1 to 5. The normalized figure of merit Z is simply referred to as “normalized Z” as well.

(Normalized Z)=(Figure of merit Z of each of examples or comparative examples)/(Figure of merit Z of standard comparative example)

A: The normalized Z was equal to or greater than 2.0.

B: The normalized Z was equal to or greater than 1.5 and less than 2.0.

C: The normalized Z was equal to or greater than 0.8 and less than 1.5.

D: The normalized Z was less than 0.8.

((Evaluation of High-Temperature Durability))

The thermoelectric conversion element of each of the examples and the comparative examples was put into a constant-temperature tank and kept as it was at 150° C. for 7 days. A rate of change in resistance was calculated by the following equation and evaluated based on the following standards.

(Rate of change in resistance)=(Resistance of thermoelectric conversion element after being kept at 150° C. for 7 days)/(Resistance of just prepared thermoelectric conversion element)

A: The rate of change in resistance was less than 1.5.

B: The rate of change in resistance was equal to or higher than 1.5 and less than 2.0.

C: The rate of change in resistance was equal to or higher than 2.0 and less than 2.5.

D: The rate of change in resistance was equal to or higher than 2.5 and less than 3.0.

E: The rate of change in resistance was equal to or higher than 3.0.

(Evaluation of Thermoelectric Conversion Module)

((Output))

FIG. 6 is a view for illustrating a method for evaluating the thermoelectric conversion modules in examples. As shown in FIG. 6, a power generating layer side of the thermoelectric conversion module 200 was protected with an aramid film 310. Furthermore, the lower portion of the thermoelectric conversion module 200 was fixed by being sandwiched between copper plates 320 installed on a hot plate 330 such that the lower portion of the thermoelectric conversion module 200 could be efficiently heated.

Then, terminals (not shown in the drawing) of a source meter (manufactured by Keithley Instruments, Inc.) were mounted on extraction electrodes (not shown in the drawing) at both ends of the thermoelectric conversion module 200, and the temperature of the hot plate 330 was caused to remain constant at 100° C. such that a temperature difference was caused in the thermoelectric conversion module 200.

The current-voltage characteristics were measured, and a short-circuit current and an open voltage were measured. From the measured results, an output was calculated by “(Output)=[(Current)×(Voltage)/4]”. Furthermore, a normalized output was calculated by the following equation and evaluated based on the following standards.

Comparative Example 1 was used as a standard comparative example for Examples 1 to 26 and Comparative Examples 1 to 5.

(Normalized output)=(Output of each of examples or comparative examples)/(Output of standard comparative example)

A: The normalized output was equal to or higher than 2.0.

B: The normalized output was equal to or higher than 1.5 and less than 2.0.

C: The normalized output was equal to or higher than 0.8 and less than 1.5.

D: The normalized output was less than 0.8.

((Evaluation of High-Temperature Durability))

The thermoelectric conversion module of each of the examples and the comparative examples was put into a constant-temperature tank and kept as it was at 150° C. for 7 days. Based on a rate of change in output calculated by the following equation, the high-temperature durability of the thermoelectric conversion module was evaluated according to the following standards.

(Rate of change in output)=(Output of thermoelectric conversion module after being kept at 150° C. for 7 days)/(Output of just prepared thermoelectric conversion module)

A: The rate of change in output was equal to or higher than 0.8.

B: The rate of change in output was equal to or higher than 0.6 and less than 0.8.

C: The rate of change in output was equal to or higher than 0.4 and less than 0.6.

D: The rate of change in output was equal to or higher than 0.2 and less than 0.4.

E: The rate of change in output was less than 0.2.

((Evaluation of Moisture-Heat Resistance))

The thermoelectric conversion module of each of the examples and the comparative examples was put into an environmental testing machine and kept as it was at 85° C. and a humidity of 85% for 7 days. Based on a rate of change in output calculated by the following equation, the moisture-heat resistance of the thermoelectric conversion module was evaluated according to the following standards.

(Rate of change in output)=(Output of thermoelectric conversion module after being kept at 85° C. and humidity of 85% for 7 days)/(Output of just prepared thermoelectric conversion module)

A: The rate of change in output was equal to or higher than 0.8.

B: The rate of change in output was equal to or higher than 0.6 and less than 0.8.

C: The rate of change in output was equal to or higher than 0.4 and less than 0.6.

D: The rate of change in output was equal to or higher than 0.2 and less than 0.4.

E: The rate of change in output was less than 0.2.

((Evaluation of Durability after Heat Cycle))

A cycle, in which the thermoelectric conversion module of each of the examples and the comparative examples was kept in a constant-temperature tank at 120° C. and −20° C. for 12 hours, was repeated 10 times (heat cycle). Based on a rate of change in output calculated by the following equation, the durability of the thermoelectric conversion module after heat cycle was evaluated according to the following standards.

Rate of change in output=(Output of thermoelectric conversion module after heat cycle)/(Output of just prepared thermoelectric conversion module)

A: The rate of change in output was equal to or higher than 0.8.

B: The rate of change in output was equal to or higher than 0.6 and less than 0.8.

C: The rate of change in output was equal to or higher than 0.4 and less than 0.6.

D: The rate of change in output was equal to or higher than 0.2 and less than 0.4.

E: The rate of change in output was less than 0.2.

<Evaluation Result>

The results of the above evaluation tests are summarized in Table 1.

TABLE 1

| | Thermoelectric conversion layer | | | | | |
|---|---|---|---|---|---|---|
| | Thermoelectric | | | Oxidation-reduction | | |
| | conversion | Type of | pKa of | potential of dopant | Polymer | Buffer layer |
| | material | dopant | dopant | (V) | compound | Material |
| Example 1 | Single-layer CNT | TCNQ | — | 0.15 | N/A | Single-layer CNT |
| Example 2 | Single-layer CNT | TCNQ | — | 0.15 | Sodium | Single-layer CNT |
| | | | | | carboxymethyl | |
| | | | | | cellulose | |
| Example 3 | Single-layer CNT | TCNQ | — | 0.15 | N/A | Single-layer CNT + |
| | | | | | | Sodium carboxymethyl |
| | | | | | | cellulose |
| Example 4 | Single-layer CNT | TCNQ | — | 0.15 | Sodium | Single-layer CNT + |
| | | | | | carboxymethyl | Sodium carboxymethyl |
| | | | | | cellulose | cellulose |
| Example 5 | Single-layer CNT | F₄-TCNQ | — | 0.52 | Guar | Single-layer CNT + |
| | | | | | gum | Guar gum |
| Example 6 | Single-layer CNT | DDQ | — | 0.50 | Sodium | Single-layer CNT + |
| | | | | | alginate | Sodium alginate |
| Example 7 | Single-layer CNT | BQ | — | −0.35 | Sodium | Single-layer CNT + |
| | | | | | carboxymethyl | Sodium carboxymethyl |
| | | | | | cellulose | cellulose |
| Example 8 | Single-layer CNT | Benzoic acid | 4.2 | — | Sodium | Single-layer CNT + |
| | | | | | carboxymethyl | Sodium carboxymethyl |
| | | | | | cellulose | cellulose |
| Example 9 | Single-layer CNT | p-Hydroxybenzoic acid | 4.6 | — | Sodium | Single-layer CNT + |
| | | | | | carboxymethyl | Sodium carboxymethyl |
| | | | | | cellulose | cellulose |
| Example 10 | Single-layer CNT | 1-Naphthoic acid | 3.7 | — | Sodium | Single-layer CNT + |
| | | | | | carboxymethyl | Sodium carboxymethyl |
| | | | | | cellulose | cellulose |
| Example 11 | Single-layer CNT | 1-Pyrenecarboxylic acid | (3 to 5) | — | Sodium | Single-layer CNT + |
| | | | | | carboxymethyl | Sodium carboxymethyl |
| | | | | | cellulose | cellulose |
| Example 12 | Single-layer CNT | 1-Pyrenebutanoic acid | (3 to 5) | — | Sodium | Single-layer CNT + |
| | | | | | carboxymethyl | Sodium carboxymethyl |
| | | | | | cellulose | cellulose |
| Example 13 | Single-layer CNT | Propionic acid | 4.9 | — | Sodium | Single-layer CNT + |
| | | | | | carboxymethyl | Sodium carboxymethyl |
| | | | | | cellulose | cellulose |
| Example 14 | Single-layer CNT | Cyclohexane carboxylic acid | 6.6 | — | Sodium | Single-layer CNT + |
| | | | | | carboxymethyl | Sodium carboxymethyl |
| | | | | | cellulose | cellulose |
| Example 15 | Single-layer CNT | Squaric acid | 2.2 | — | Sodium | Single-layer CNT + |
| | | | | | carboxymethyl | Sodium carboxymethyl |
| | | | | | cellulose | cellulose |
| Example 16 | Single-layer CNT | Adipic acid | 4.4 | — | Sodium | Single-layer CNT + |
| | | | | | carboxymethyl | Sodium carboxymethyl |
| | | | | | cellulose | cellulose |
| Example 17 | Single-layer CNT | Succinic acid | 4.2 | — | Sodium | Single-layer CNT + |
| | | | | | carboxymethyl | Sodium carboxymethyl |
| | | | | | cellulose | cellulose |
| Example 18 | Single-layer CNT | Dihydroabietic acid | (6 to 7) | — | Sodium | Single-layer CNT + |
| | | | | | carboxymethyl | Sodium carboxymethyl |
| | | | | | cellulose | cellulose |
| Example 19 | Single-layer CNT | Alginic acid | 1.5 to 3.5 | — | Sodium | Single-layer CNT + |
| | | | | | carboxymethyl | Sodium carboxymethyl |
| | | | | | cellulose | cellulose |
| Example 20 | Single-layer CNT | p-Toluenesulfonic acid | −2.8 | — | Sodium | Single-layer CNT + |
| | | | | | carboxymethyl | Sodium carboxymethyl |
| | | | | | cellulose | cellulose |
| Example 21 | Single-layer CNT | Camphorsulfonic acid | 1.2 | — | Sodium | Single-layer CNT + |
| | | | | | carboxymethyl | Sodium carboxymethyl |
| | | | | | cellulose | cellulose |
| Example 22 | Single-layer CNT | Polystyrene sulfonic acid | (less than 1.5) | — | Sodium | Single-layer CNT + |
| | | | | | carboxymethyl | Sodium carboxymethyl |
| | | | | | cellulose | cellulose |
| Example 23 | Single-layer CNT | Iron (III) p-toluenesulfonate | — | — | Sodium | Single-layer CNT + |
| | | | | | carboxymethyl | Sodium carboxymethyl |
| | | | | | cellulose | cellulose |
| Example 24 | Single-layer CNT | Iron (III) chloride | — | — | Sodium | Single-layer CNT + |
| | | | | | carboxymethyl | Sodium carboxymethyl |
| | | | | | cellulose | cellulose |
| Example 25 | Single-layer | Dopant 1 | — | — | N/A | Single-layer |
| | CNT/P3HT | | | | | CNT + P3HT |
| Example 26 | Single-layer CNT | TCNQ | — | 0.15 | Sodium | Single-layer |
| | | | | | carboxymethyl | CNT + Sodium |
| | | | | | cellulose | carboxymethyl cellulose |
| | | | | | | (formed simultaneously |
| | | | | | | with thermoelectric |
| | | | | | | conversion layer) |
| Comparative | Single-layer CNT | TCNQ | — | 0.15 | N/A | N/A |
| Example 1 | | | | | | |
| Comparative | Single-layer CNT | TCNQ | — | 0.15 | Sodium | N/A |
| Example 2 | | | | | carboxymethyl | |
| | | | | | cellulose | |
| Comparative | Single-layer CNT | TCNQ | — | 0.15 | N/A | Single-layer |
| Example 3 | | | | | | CNT + TCNQ |
| Comparative | Single-layer CNT | TCNQ | — | 0.15 | N/A | Graphite + |
| Example 4 | | | | | | Sodium carboxymethyl |
| | | | | | | cellulose |
| Comparative | Single-layer CNT | TCNQ | — | 0.15 | Sodium | Tin oxide |
| Example 5 | | | | | carboxymethyl | |
| | | | | | cellulose | |

| | | Element performance | | | | Module performance | | | |
|---|---|---|---|---|---|---|---|---|---|
| | | | | | Durability | | Durability | | |
| | Dopant | Electric | Seebeck | Figure | High | | High | Moisture | Heat |
| | ratio | conductivity | coefficient | of merit Z | temperature | Output | temperature | and heat | cycle |
| Example 1 | C | C | B | C | C | C | C | C | C |
| Example 2 | B | B | B | B | B | B | B | B | B |
| Example 3 | B | B | B | B | B | B | B | B | B |
| Example 4 | A | B | B | A | A | A | A | A | A |
| Example 5 | A | A | B | A | A | A | A | A | A |
| Example 6 | A | B | A | A | A | A | A | A | A |
| Example 7 | A | C | B | B | A | A | A | A | A |
| Example 8 | A | B | A | A | A | A | A | A | A |
| Example 9 | A | B | A | A | A | A | A | A | A |
| Example 10 | A | B | A | A | A | A | A | A | A |
| Example 11 | A | B | A | A | A | A | A | A | A |
| Example 12 | A | B | A | A | A | A | A | A | A |
| Example 13 | A | B | A | A | A | A | A | A | A |
| Example 14 | A | B | A | A | A | A | A | A | A |
| Example 15 | A | B | A | A | A | A | A | A | A |
| Example 16 | A | B | A | A | A | A | A | A | A |
| Example 17 | A | B | A | A | A | A | A | A | A |
| Example 18 | A | B | A | A | A | A | A | A | A |
| Example 19 | A | B | A | A | A | A | A | A | A |
| Example 20 | A | A | B | A | B | A | B | B | B |
| Example 21 | A | A | B | A | B | A | B | B | B |
| Example 22 | A | A | B | A | B | A | B | B | B |
| Example 23 | A | A | C | A | B | A | B | B | B |
| Example 24 | A | A | C | A | B | B | B | B | B |
| Example 25 | A | B | B | B | B | B | B | B | B |
| Example 26 | A | B | B | A | A | A | A | A | A |
| Comparative | — | C | B | C | E | C | E | E | E |
| Example 1 | | | | | | | | | |
| Comparative | — | B | B | B | E | B | E | E | E |
| Example 2 | | | | | | | | | |
| Comparative | D | B | B | B | D | B | D | D | D |
| Example 3 | | | | | | | | | |
| Comparative | B | D | B | D | C | D | C | C | C |
| Example 4 | | | | | | | | | |
| Comparative | A | D | B | D | A | D | B | B | B |
| Example 5 | | | | | | | | | |

As shown in Table 1, it was understood that all of the thermoelectric conversion elements of the examples have excellent thermoelectric conversion performance (figure of merit Z) and excellent high-temperature durability. Furthermore, it was revealed that all of the thermoelectric conversion modules of the examples have excellent output and exhibit excellent durability under various conditions.

From the comparison between Example 1 and Example 2, it was revealed that in a case where the thermoelectric conversion layer containing a polymer compound is used (Example 2), the figure of merit Z and the high-temperature durability of the thermoelectric conversion element are further improved, and the output and the durability of the thermoelectric conversion module are further improved.

From the comparison of Examples 8 to 22, it was revealed that in a case where a Brønsted acid having pKa within a range of 1.5 to 8 is used as a dopant (Examples 8 to 19), the high-temperature durability of the thermoelectric conversion element is further improved, and the durability of the thermoelectric conversion module is further improved.

In contrast, it was revealed that because the thermoelectric conversion elements of Comparative Example 1 and Comparative Example 2 exhibit poor high-temperature durability because they have no buffer layer. Furthermore, it was revealed that the thermoelectric conversion modules of Comparative Example 1 and Comparative Example 2 exhibit poor durability under various conditions.

It was revealed that although the thermoelectric conversion element of Comparative Example 3 has a buffer layer, the dopant ratio thereof is higher than 0.1, and hence the high-temperature durability is poor. In addition, it was revealed that the thermoelectric conversion module of Comparative Example 3 exhibits poor durability under various conditions.

Furthermore, it was revealed that because the thermoelectric conversion layer and the buffer layer of the thermoelectric conversion elements of Comparative Example 4 and Comparative Example 5 contain different types of thermoelectric conversion materials, the figure of merit Z is poor. In addition, it was revealed that the thermoelectric conversion modules of Comparative Example 4 and Comparative Example 5 have a poor output.

### Examples 27 and 28 and Comparative Example 6

By using the thermoelectric conversion element and the thermoelectric conversion module of Comparative Example 6 as standard comparative examples, the thermoelectric conversion elements and the thermoelectric conversion modules of Examples 27 and 28 and Comparative Example 6 were evaluated in terms of various items.

The thermoelectric conversion element and the thermoelectric conversion module used in Example 27 were obtained in the same manner as that in Example 4, except that the single-layer carbon nanotubes were replaced with double-layered carbon nanotubes.

In Example 28, for comparing single-layer carbon nanotubes with double-layered carbon nanotubes, the thermoelectric conversion element and the thermoelectric conversion module manufactured in Example 4 were prepared and used as a thermoelectric conversion element and a thermoelectric conversion module.

The thermoelectric conversion element and the thermoelectric conversion module used in Comparative Example 6 were obtained in the same manner as in Example 28, except that a buffer layer was not formed.

<Evaluation Test>

For the thermoelectric conversion elements of Example 27, Example 28, and Comparative Example 6, the dopant ratio was evaluated by the same method and the same evaluation standards as those in Example 1.

The electric conductivity, the thermoelectric conversion performance (figure of merit Z), and the high-temperature durability of the thermoelectric conversion elements of Examples 27 and 28 and Comparative Example 6 and the output of the thermoelectric conversion modules of Examples 27 and 28 and Comparative Example 6 were evaluated by the same method and the same evaluation standards as those in Example 1, except that Comparative Example 6 was used as a standard comparative example.

In addition, the high-temperature durability, the moisture-heat resistance, and the durability after heat cycle of the thermoelectric conversion modules of Examples 27 and 28 and Comparative Example 6 were evaluated by the same method and the same evaluation standards as those in Example 1.

Furthermore, the Seebeck coefficient of the thermoelectric conversion elements of Example 27, Example 28, and Comparative Example 6 was evaluated by the same method as that in Example 1, except that Comparative Example 6 was used as a standard comparative example, and the following evaluation standards were used.

A: The normalized Seebeck coefficient was equal to or higher than 2.0.

B: The normalized Seebeck coefficient was less than 2.0.

<Evaluation Result>

The results of the above evaluation tests are summarized in Table 2.

TABLE 2

| | Thermoelectric conversion layer | | | | | | |
|---|---|---|---|---|---|---|---|
| | Thermoelectric | | | Oxidation-reduction | | | |
| | conversion | Type of | pKa of | potential of dopant | Polymer | Buffer layer | Dopant |
| | material | dopant | dopant | (V) | compound | Material | ratio |
| Example 27 | Double-layered | TCNQ | — | 0.15 | Sodium | Double-layered | A |
| | CNT | | | | carboxymethyl | CNT + Sodium | |
| | | | | | cellulose | carboxymethyl | |
| | | | | | | cellulose | |
| Example 28 | Single-layer | TCNQ | — | 0.15 | Sodium | Single-layer | A |
| | CNT | | | | carboxymethyl | CNT + Sodium | |
| | | | | | cellulose | carboxymethyl | |
| | | | | | | cellulose | |
| Comparative | Double-layered | TCNQ | — | 0.15 | Sodium | N/A | — |
| Example 6 | CNT | | | | carboxymethyl | | |
| | | | | | cellulose | | |

| | Element performance | | | | Module performance | | | |
|---|---|---|---|---|---|---|---|---|
| | | | | Durability | | Durability | | |
| | Electric | Seebeck | Figure of | High | | High | Moisture | Heat |
| | conductivity | coefficient | merit Z | temperature | Output | temperature | and heat | cycle |
| Example 27 | C | B | C | A | B | A | A | A |
| Example 28 | C | A | B | A | A | A | A | A |
| Comparative | C | B | C | E | C | E | E | E |
| Example 6 | | | | | | | | |

As shown in Table 2, it was understood that all of the thermoelectric conversion elements of the examples have excellent thermoelectric conversion performance (figure of merit Z) and excellent high-temperature durability. Furthermore, it was revealed that all of the thermoelectric conversion modules of the examples have excellent output and exhibit excellent durability under various conditions.

From the comparison between Example 27 and Example 28, it was revealed that in a case where the thermoelectric conversion layer containing single-layer CNT is used (Example 28), the electric conductivity, the Seebeck coefficient, and the figure of merit Z of the thermoelectric conversion element are further improved, and the output of the thermoelectric conversion module is further improved.

In contrast, it was revealed that because the thermoelectric conversion element of Comparative Example 6 has no buffer layer, the element exhibited poor high-temperature durability. In addition, it was revealed that the thermoelectric conversion module of Comparative Example 6 exhibits poor durability under various conditions.

### Examples 29 and 30 and Comparative Example 7

By using the thermoelectric conversion element and the thermoelectric conversion module of Comparative Example 7 as standard comparative examples, the thermoelectric conversion elements and the thermoelectric conversion modules of Examples 29 and 30 and Comparative Example 7 were evaluated in terms of various items.

### Example 29

(Manufacturing of Thermoelectric Conversion Element)

A 1 cm (width)×11 cm (length) mold was installed on a polyimide substrate and filled with a material obtained by adding ethylene glycol to an aqueous dispersion liquid (manufactured by Heraeus Holding, trade name: “Clevios”) of poly(3,4-ethylenedioxythiophene)-poly(styrenesulfonate) (PEDOT-PSS). The material was dried for 30 minutes at 100° C. and then for 1 hour at 120° C., thereby forming a thermoelectric conversion layer. The thermoelectric conversion layer was spin-coated (1,000 rpm, 60 seconds) with a chlorobenzene solution (10 mg/mL) of poly(3-hexylthiophene) (manufactured by Sigma-Aldrich Co. LLC., hereinafter, referred to as “P3HT” as well) and dried for 30 minutes at 120° C., thereby forming a buffer layer. Then, on the buffer layer at both ends of the thermoelectric conversion layer, two silver pastes (manufactured by FUJIKURA KASEI CO., LTD.) having a size of 2 cm×2 cm were printed at an interval of 10 cm, and the pastes were dried for 1 hour at 110° C., thereby forming silver electrodes. In this way, a thermoelectric conversion element of Example 29 was obtained.

(Manufacturing of Thermoelectric Conversion Module)

3 mm (width)×6 mm (length) seventeen molds were installed on a polyimide substrate and filled with a material obtained by adding ethylene glycol to an aqueous dispersion liquid (manufactured by Heraeus Holding, trade name: “Clevios”) of poly(3,4-ethylenedioxythiophene)-poly(styrenesulfonate) (PEDOT-PSS). The material was dried for 30 minutes at 100° C. and then for 1 hour at 120° C., thereby forming thermoelectric conversion layers. The thermoelectric conversion layers were spin-coated (1,000 rpm, 60 seconds) with a chlorobenzene solution (10 mg/mL) of poly(3-hexylthiophene) (manufactured by Sigma-Aldrich Co. LLC.) and dried for 30 minutes at 120° C., thereby forming buffer layers. In order to make the thermoelectric conversion layers electrically insulated from each other, the surplus buffer layers were removed using a cotton swab. Then, a silver paste (manufactured by FUJIKURA KASEI CO., LTD.) was printed thereon such that the thermoelectric conversion layers were connected to each other in series, and the silver paste was dried for 1 hour at 110° C. so as to form silver electrodes, thereby obtaining a thermoelectric conversion module of Example 29.

### Example 30 and Comparative Example 7

In Example 30, for comparing single-layer carbon nanotubes with PEDOT-PSS, the thermoelectric conversion element and the thermoelectric conversion module manufactured in Example 4 were prepared and used as a thermoelectric conversion element and a thermoelectric conversion module.

A thermoelectric conversion element and a thermoelectric conversion module used in Comparative Example 7 were obtained in the same manner as that in Example 30, except that a buffer layer was not formed.

<Evaluation Test>

For the thermoelectric conversion elements of Examples 29 and 30 and Comparative Example 7, the dopant ratio was evaluated by the same method and the same evaluation standards as those in Example 1.

Furthermore, the electric conductivity, the figure of merit Z, the high-temperature durability of the thermoelectric conversion elements of Examples 29 and 30 and Comparative Example 7 and the output of the thermoelectric conversion modules of Examples 29 and 30 and Comparative Example 7 were evaluated by the same method and the same evaluation standards as those in Example 1, except that Comparative Example 7 was used as a standard comparative example.

In addition, the high-temperature durability, the moisture-heat resistance, and the durability after heat cycle of the thermoelectric conversion modules of Examples 29 and 30 and Comparative Example 7 were evaluated by the same method and the same evaluation standards as those in Example 1.

The Seebeck coefficient of the thermoelectric conversion elements of Examples 29 and 30 and Comparative Example 7 was evaluated in the same manner as that in Example 27, except that Comparative Example 7 was used as a standard comparative example.

<Evaluation Result>

The results of the above evaluation tests are summarized in Table 3.

TABLE 3

| | Thermoelectric conversion layer | | | | | | |
|---|---|---|---|---|---|---|---|
| | Thermoelectric | | | Oxidation-reduction | | | |
| | conversion | Type of | pKa of | potential of dopant | Polymer | Buffer layer | Dopant |
| | material | dopant | dopant | (V) | compound | Material | ratio |
| Example 29 | PEDOT-PSS | PSS | (Less than 1.5) | — | PEDOT-PSS | P3HT | A |
| Example 30 | Single-layer | TCNQ | — | 0.15 | Sodium | Single-layer | A |
| | CNT | | | | carboxymethyl | CNT + sodium | |
| | | | | | cellulose | carboxymethyl | |
| | | | | | | cellulose | |
| Comparative | PEDOT-PSS | PSS | (Less than 1.5) | — | PEDOT-PSS | N/A | — |
| Example 7 | | | | | | | |

| | Element performance | | | | Module performance | | | |
|---|---|---|---|---|---|---|---|---|
| | | | | Durability | | Durability | | |
| | Electric | Seebeck | Figure of | High | | High | Moisture | Heat |
| | conductivity | coefficient | merit Z | temperature | Output | temperature | and heat | cycle |
| Example 29 | C | B | C | A | B | A | A | A |
| Example 30 | A | A | A | A | A | A | A | A |
| Comparative | C | B | C | E | C | E | E | E |
| Example 7 | | | | | | | | |

As shown in Table 3, it was understood that all of the thermoelectric conversion elements of the examples have excellent thermoelectric conversion performance (figure of merit Z) and excellent high-temperature durability. Furthermore, it was revealed that all of the thermoelectric conversion modules of the examples have excellent output and exhibit excellent durability under various conditions.

From the comparison between Example 29 and Example 30, it was revealed that in a case where a thermoelectric conversion layer containing single-layer CNT is used (Example 30), the electric conductivity, the Seebeck coefficient, and the figure of merit Z of the thermoelectric conversion element are further improved, and the output of the thermoelectric conversion module is further improved.

In contrast, it was revealed that because thermoelectric conversion element of Comparative Example 7 has no buffer layer, the element exhibited poor high-temperature durability. In addition, it was revealed that the thermoelectric conversion module of Comparative Example 7 exhibits poor durability under various conditions.

### Examples 31 and 32 and Comparative Example 8

By using the thermoelectric conversion element and the thermoelectric conversion module of Comparative Example 8 as standard comparative examples, the thermoelectric conversion elements and the thermoelectric conversion modules of Examples 31 and 32 and Comparative Example 8 were evaluated in terms of various items.

The thermoelectric conversion element and the thermoelectric conversion module used in Example 31 were obtained in the same manner as that in Example 4, except that carbon nanotubes were replaced with graphite, and sodium carboxymethyl cellulose (low-viscosity product) was replaced with 100 mg of sodium carboxymethyl cellulose (manufactured by Sigma-Aldrich Co. LLC, high-viscosity product).

In Example 32, for comparing single-layer carbon nanotubes with graphite, the thermoelectric conversion element and the thermoelectric conversion module manufactured in Example 4 were prepared and used as a thermoelectric conversion element and a thermoelectric conversion module.

The thermoelectric conversion element and the thermoelectric conversion module used in Comparative Example 8 were obtained in the same manner as that in Example 31, except that a buffer layer was not formed.

<Evaluation Test>

For the thermoelectric conversion elements of Examples 31 and 32 and Comparative Example 8, the dopant ratio was evaluated by the same method and the same evaluation standards as those in Example 1.

Furthermore, the electric conductivity, the figure of merit Z, and the high-temperature durability of the thermoelectric conversion elements of Examples 31 and 32 and Comparative Example 8 and the output of the thermoelectric conversion modules of Examples 31 and 32 and Comparative Example 8 were evaluated by the same method and the same evaluation standards as those in Example 1, except that Comparative Example 8 was used as a standard comparative example.

In addition, the high-temperature durability, the moisture-heat resistance, and the durability after the heat cycle of the thermoelectric conversion modules of Examples 31 and 32 and Comparative Example 8 were evaluated by the same method and the same evaluation standards as those in Example 1.

The Seebeck coefficient of the thermoelectric conversion elements of Examples 31 and 32 and Comparative Example 8 was evaluated in the same manner as that in Example 27, except that Comparative Example 8 was used as a standard comparative example.

<Evaluation Result>

The results of the above evaluation tests are summarized in Table 4.

TABLE 4

| | Thermoelectric conversion layer | | | | | | |
|---|---|---|---|---|---|---|---|
| | Thermoelectric | | | Oxidation-reduction | | | |
| | conversion | Type of | pKa of | potential of dopant | Polymer | Buffer layer | Dopant |
| | material | dopant | dopant | (V) | compound | Material | ratio |
| Example 31 | Graphite | TCNQ | — | 0.15 | Sodium | Graphite + | A |
| | | | | | carboxymethyl | Sodium | |
| | | | | | cellulose | carboxymethyl | |
| | | | | | | cellulose | |
| Example 32 | Single-layer CNT | TCNQ | — | 0.15 | Sodium | Single-layer | A |
| | | | | | carboxymethyl | CNT + | |
| | | | | | cellulose | Sodium | |
| | | | | | | carboxymethyl | |
| | | | | | | cellulose | |
| Comparative | Graphite | TCNQ | — | 0.15 | Sodium | N/A | — |
| Example 8 | | | | | carboxymethyl | | |
| | | | | | cellulose | | |

| | Element performance | | | | Module performance | | | |
|---|---|---|---|---|---|---|---|---|
| | | | | Durability | | Durability | | |
| | Electric | Seebeck | Figure of | High | | High | Moisture | Heat |
| | conductivity | coefficient | merit Z | temperature | Output | temperature | and heat | cycle |
| Example 31 | C | B | C | A | B | A | A | A |
| Example 32 | A | A | A | A | A | A | A | A |
| Comparative | C | B | C | E | C | E | E | E |
| Example 8 | | | | | | | | |

As shown in Table 4, it was understood that all of the thermoelectric conversion elements of the examples have excellent figure of merit Z and excellent high-temperature durability. Furthermore, it was revealed that all of the thermoelectric conversion modules of the examples have excellent output and exhibit excellent durability under various conditions.

From the comparison between Example 31 and Example 32, it was revealed that in a case where a thermoelectric conversion layer containing single-layer CNT is used (Example 32), the electric conductivity, the Seebeck coefficient, and the figure of merit Z of the thermoelectric conversion element are further improved, and the output of the thermoelectric conversion module is further improved.

In contrast, it was revealed that because the thermoelectric conversion element of Comparative Example 8 has no buffer layer, the element exhibited poor high-temperature durability. In addition, it was revealed that the thermoelectric conversion module of Comparative Example 8 exhibits poor durability under various conditions.

### EXPLANATION OF REFERENCES

1A, 1B, 1C, 1D: thermoelectric conversion element
2, 120: substrate
3A, 3B, 3C, 3D, 26: first electrode
4A, 4B, 4C, 4D: second electrode
5, 150: thermoelectric conversion layer
6: protective substrate
8A, 8B, 8C: first buffer layer
8D, 180: buffer layer
9A, 9B, 9C: second buffer layer
130: electrode
132: wiring
200: thermoelectric conversion module
310: aramid film
320: copper plate
330: hot plate

What is claimed is:

1. A thermoelectric conversion element, comprising:
a thermoelectric conversion layer containing an organic thermoelectric conversion material and a dopant;
a pair of electrodes disposed at positions separated from each other; and
a buffer layer which is disposed between the thermoelectric conversion layer and each of the electrodes and electrically connects the thermoelectric conversion layer and the electrodes to each other,
wherein the buffer layer contains the same material as the organic thermoelectric conversion material contained in the thermoelectric conversion layer,
the buffer layer does not contain a dopant or contains a dopant, and
in a case where the buffer layer contains a dopant, a ratio of the dopant contained in the buffer layer to the dopant contained in the thermoelectric conversion layer is equal to or lower than 0.1.

2. The thermoelectric conversion element according to claim 1,
wherein at least one of the thermoelectric conversion layer or the buffer layer contains a polymer compound.

3. The thermoelectric conversion element according to claim 1,
wherein the dopant contains at least one kind of acid component selected from the group consisting of a Brønsted acid, a Lewis acid, an oxidant, and an acid generator.

4. The thermoelectric conversion element according to claim 3,
wherein in a case where the dopant contains the Brønsted acid, pKa of the Brønsted acid is 1.5 to 8.

5. The thermoelectric conversion element according to claim 3,
wherein in a case where the dopant contains the oxidant, an oxidation-reduction potential of the oxidant with respect to a saturated calomel reference electrode is equal to or higher than −0.1 V.

6. The thermoelectric conversion element according to claim 1,
wherein the buffer layer substantially does not contain a dopant.

7. The thermoelectric conversion element according to claim 1,
wherein the organic thermoelectric conversion material is a carbon material.

8. The thermoelectric conversion element according to claim 7,
wherein the carbon material is a carbon nanotube.

9. The thermoelectric conversion element according to claim 8,
wherein the carbon nanotube is a single-layer carbon nanotube.

10. A method for manufacturing the thermoelectric conversion element according to claim 1, wherein a step of forming the thermoelectric conversion layer and a step of forming the buffer layer are simultaneously performed.

11. A thermoelectric conversion module comprising:
a plurality of the thermoelectric conversion elements according to claim 1.

12. A method for manufacturing the thermoelectric conversion module according to claim 11,
wherein a step of forming the thermoelectric conversion layer and a step of forming the buffer layer are simultaneously performed.

13. The thermoelectric conversion element according to claim 2,
wherein the dopant contains at least one kind of acid component selected from the group consisting of a Brønsted acid, a Lewis acid, an oxidant, and an acid generator.

14. The thermoelectric conversion element according to claim 2,
wherein the buffer layer substantially does not contain a dopant.

15. The thermoelectric conversion element according to claim 3,
wherein the buffer layer substantially does not contain a dopant.

15. The thermoelectric conversion element according to claim 3,
wherein the buffer layer substantially does not contain a dopant.

16. The thermoelectric conversion element according to claim 4,
wherein the buffer layer substantially does not contain a dopant.

17. The thermoelectric conversion element according to claim 5,
wherein the buffer layer substantially does not contain a dopant.

18. The thermoelectric conversion element according to claim 13,
wherein the buffer layer substantially does not contain a dopant.

19. The thermoelectric conversion element according to claim 2,
wherein the organic thermoelectric conversion material is a carbon material.

20. The thermoelectric conversion element according to claim 3,
wherein the organic thermoelectric conversion material is a carbon material.
